(19) United States
(12) Patent Application Publication
(10) Pub. No.: US 2025/0267935 A1
(43) Pub. Date: Aug. 21, 2025

(54) THREE-DIMENSIONAL SEMICONDUCTOR DEVICE AND METHOD OF FABRICATING THE SAME

(71) Applicant: SAMSUNG ELECTRONICS CO., LTD., Suwon-si (KR)

(72) Inventor: JINMYOUNG LEE, Suwon-si (KR)

(73) Assignee: SAMSUNG ELECTRONICS CO., LTD., Suwon-si (KR)

(21) Appl. No.: 18/887,603

(22) Filed: Sep. 17, 2024

(30) Foreign Application Priority Data
Feb. 20, 2024 (KR) 10-2024-0024476

(51) Int. Cl. H01L 27/092; H01L 21/822; H01L 21/8238; H01L 29/06; H01L 29/417; H01L 29/423; H01L 29/49; H01L 29/66; H01L 29/775; H01L 29/786

(52) U.S. Cl. CPC H10D 84/856; H10D 30/014; H10D 30/43; H10D 30/6729; H10D 30/6735; H10D 30/6739; H10D 30/6757; H10D 62/121; H10D 64/017; H10D 84/0167; H10D 84/017; H10D 84/0181; H10D 84/0186; H10D 84/038; H10D 88/01

(57) ABSTRACT

A three-dimensional semiconductor device is provided. The device includes: a first active region on a substrate, the first active region including a first source/drain pattern that is connected to a first channel pattern; a second active region stacked on the first active region, and including a second source/drain pattern that is connected to a second channel pattern; a gate electrode disposed on the first and second channel patterns; and a first ferroelectric pattern interposed between the substrate and the first channel pattern. The first channel pattern includes a first semiconductor pattern and a second semiconductor pattern, which are spaced apart from each other in a vertical direction perpendicular to a top surface of the substrate. The first ferroelectric pattern is interposed between the substrate and the first semiconductor pattern. The gate electrode includes a first gate electrode interposed between the first and second semiconductor patterns.

### CROSS-REFERENCE TO RELATED APPLICATIONS

This U.S. non-provisional patent application claims priority under 35 U.S.C. § 119 to Korean Patent Application No. 10-2024-0024476, filed on Feb. 20, 2024, in the Korean Intellectual Property Office, the disclosure of which is hereby incorporated by reference in its entirety.

### BACKGROUND

The present disclosure relates to a three-dimensional semiconductor device and a method of fabricating the same, and in particular, to a three-dimensional semiconductor device including a field effect transistor and a method of fabricating the same.

A semiconductor device includes an integrated circuit consisting of metal-oxide-semiconductor field-effect transistors (MOSFETs). To meet an increasing demand for a semiconductor device with a small pattern size and a reduced design rule, the MOSFETs are being aggressively scaled down. The scale-down of the MOSFETs may lead to deterioration in operational properties of the semiconductor device. A variety of studies are being conducted to overcome technical limitations associated with the scale-down of the semiconductor device and to realize high-performance semiconductor devices.

### SUMMARY

One or more embodiments provide a three-dimensional semiconductor device with improved reliability.

One or more embodiments provide a method of fabricating a three-dimensional semiconductor device with improved reliability.

According to an aspect of an embodiment, a three-dimensional semiconductor device, including: a first active region on a substrate, the first active region including a first channel pattern and a first source/drain pattern that is connected to the first channel pattern; a second active region stacked on the first active region, the second active region including a second channel pattern and a second source/drain pattern that is connected to the second channel pattern; a gate electrode disposed on the first and second channel patterns; and a first ferroelectric pattern interposed between the substrate and the first channel pattern. The first channel pattern includes a first semiconductor pattern and a second semiconductor pattern, which are spaced apart from each other in a vertical direction perpendicular to a top surface of the substrate. The first ferroelectric pattern is interposed between the substrate and the first semiconductor pattern and is disposed at a side of the first source/drain pattern. The gate electrode includes a first gate electrode interposed between the first and second semiconductor patterns.

According to another aspect of an embodiment, a three-dimensional semiconductor device includes: a first active region on a substrate, the first active region including a first channel pattern and first source/drain patterns, which are disposed at opposite sides of the first channel pattern, wherein the first channel pattern includes a plurality of lower semiconductor patterns, which are spaced apart from each other in a vertical direction perpendicular to a top surface of the substrate; a second active region stacked on the first active region, the second active region including a second channel pattern and second source/drain patterns, which are disposed at opposite sides of the second channel pattern; a gate electrode disposed on the first and second channel patterns, the gate electrode including a first gate electrode between the first source/drain patterns, a second gate electrode between the second source/drain patterns, and an outer gate electrode on the second channel pattern; and a first ferroelectric pattern interposed between a lowermost one of the plurality of lower semiconductor patterns and the substrate, and between the first source/drain patterns.

According to another aspect of an embodiment, a three-dimensional semiconductor device includes: a substrate including an active pattern; a lower insulating layer disposed on the active pattern; a first active region on the lower insulating layer, the first active region including a first channel pattern and first source/drain patterns disposed at opposite sides of the first channel pattern, the first channel pattern including a first semiconductor pattern and a second semiconductor pattern that is spaced apart from the first semiconductor pattern in a vertical direction perpendicular to a top surface of the substrate; a second active region stacked on the first active region, the second active region including a second channel pattern and second source/drain patterns disposed at opposite sides of the second channel pattern, the second channel pattern including a third semiconductor pattern and a fourth semiconductor pattern that is spaced apart from the third semiconductor pattern in the vertical direction; a gate electrode disposed on the first and second channel patterns, and extending in the vertical direction; an intermediate insulating layer interposed between the first channel pattern and the second channel pattern; a first ferroelectric pattern interposed between the substrate and the first semiconductor pattern, and between the first source/drain patterns; and a second ferroelectric pattern provided on the fourth semiconductor pattern and interposed between the second source/drain patterns.

### BRIEF DESCRIPTION OF DRAWINGS

The above and other aspects and features will be more apparent from the following description of embodiments, taken in conjunction with the accompanying drawings.

FIG. 1 is a plan view illustrating a three-dimensional semiconductor device according to an embodiment.

FIGS. 2A, 2B, 2C and 2D are sectional views taken along lines A-A′, B-B′, C-C′, and D-D′, respectively, of FIG. 1, according to an embodiment.

FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A and 16B are sectional views illustrating a method of fabricating a semiconductor device according to an embodiment.

FIGS. 17 to 26 are sectional views, which are respectively taken along the line A-A′ of FIG. 1 to illustrate three-dimensional semiconductor devices according to embodiments.

### DETAILED DESCRIPTION

Hereinafter, embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

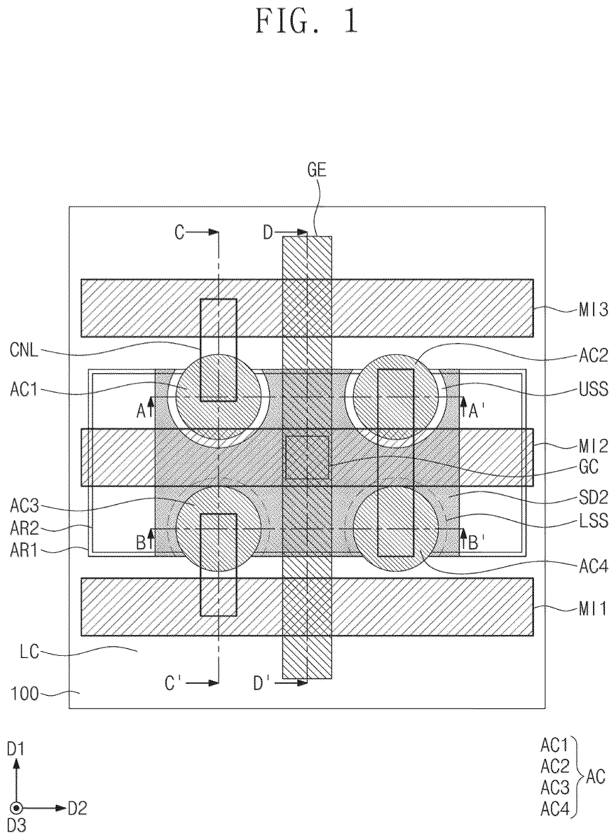

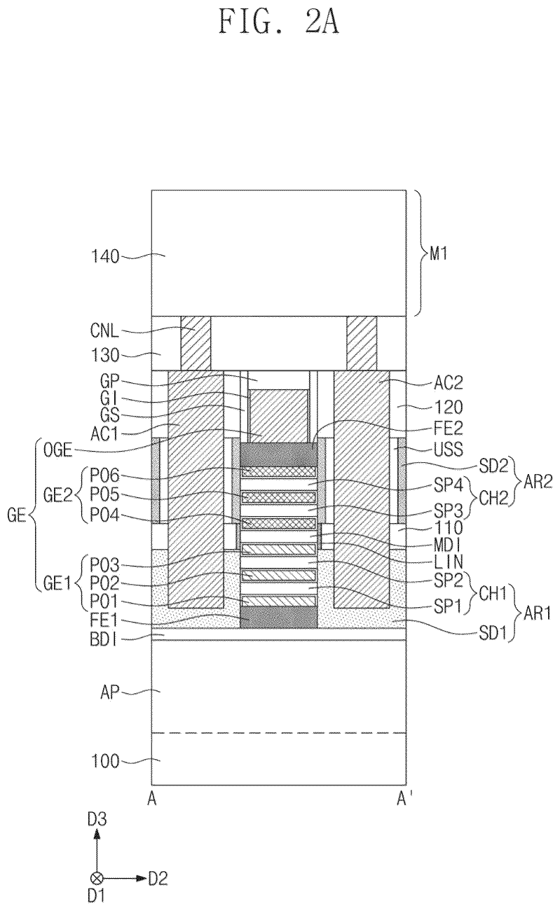

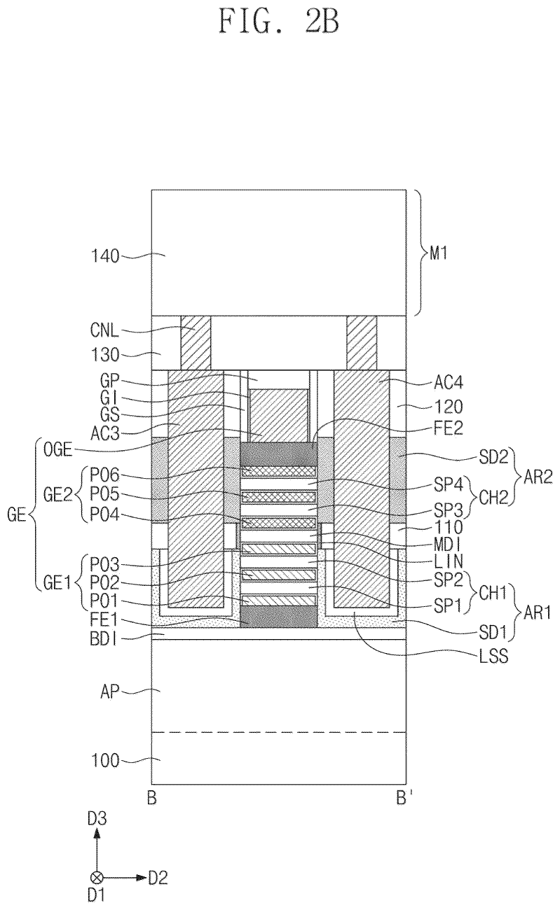

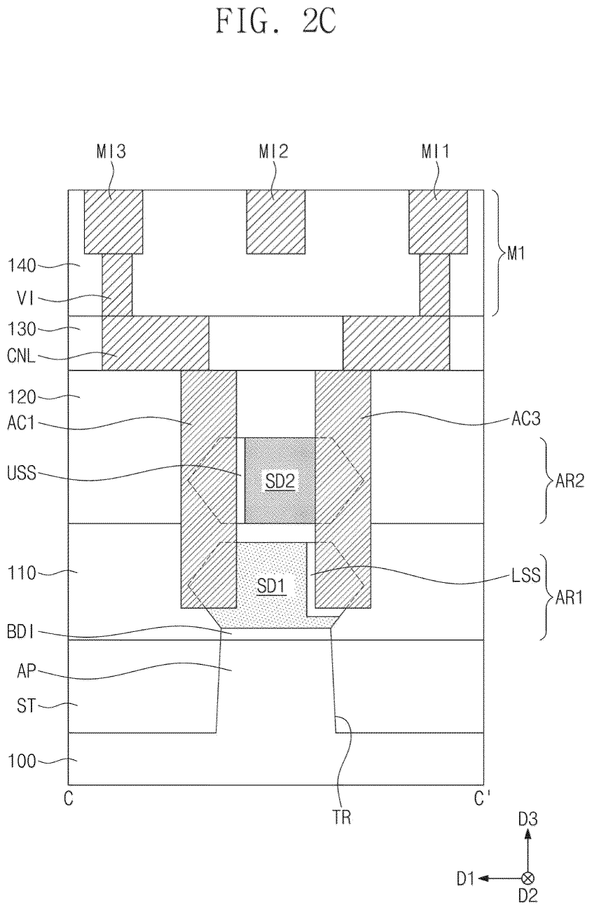

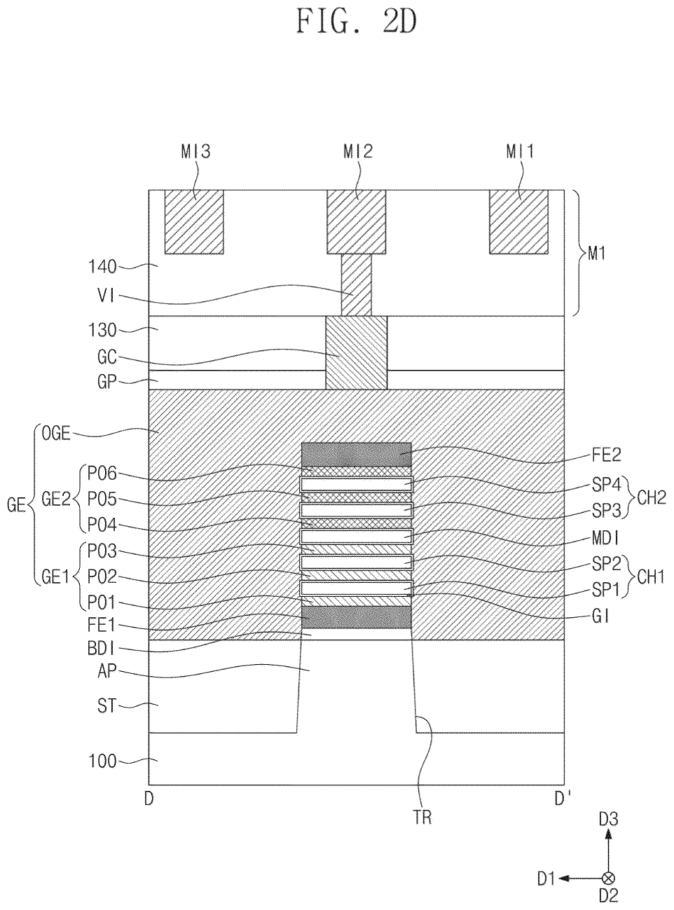

FIG. 1 is a plan view illustrating a three-dimensional semiconductor device according to an embodiment. FIGS. 2A to 2D are sectional views taken along lines A-A′, B-B′, C-C′, and D-D′, respectively, of FIG. 1.

Referring to FIGS. 1 and 2A to 2D, a substrate 100 including an active pattern AP and a device isolation layer ST may be provided. The active pattern AP may be defined by a trench TR, which is formed in an upper portion of the substrate 100. The active pattern AP may be a vertically-protruding portion of the substrate 100. When viewed in a plan view, the active pattern AP may have a bar-shape that extends in a second direction D2. The device isolation layer ST may fill the trench TR. The device isolation layer ST may include a silicon oxide layer. A top surface of the device isolation layer ST may be coplanar with or lower than a top surface of the active pattern AP. The device isolation layer ST may not cover first and second channel patterns CH1 and CH2 to be described below. In an embodiment, the device isolation layer ST may be formed of or include, for example, silicon oxide. The substrate 100 may be a semiconductor substrate, which is formed of or includes silicon, germanium, silicon germanium, or compound semiconductor materials. In an embodiment, the substrate 100 may be a silicon wafer.

A lower insulating layer BDI may be disposed on the active pattern AP. The lower insulating layer BDI may be formed of or include at least one of insulating materials (e.g., silicon oxide, silicon nitride, and/or silicon oxynitride).

A first active region AR1 and a second active region AR2, which are sequentially stacked on the lower insulating layer BDI, may be disposed. One of the first and second active regions AR1 and AR2 may be a p type metal-oxide-semiconductor field-effect transistors (MOSFET) (PMOSFET) region, and the other of the first and second active regions AR1 and AR2 may be an n type metal-oxide-semiconductor field-effect transistor (NMOSFET) region. Each of the MOSFETs of the first and second active regions AR1 and AR2 may be vertically stacked to form a three-dimensional stack transistor.

The first active region AR1 may include a first channel pattern CH1 and first source/drain patterns SD1, which are disposed at both (i.e., opposite) sides of the first channel pattern CH1. The first channel pattern CH1 may be interposed between the first source/drain patterns SD1. The first channel pattern CH1 may connect the first source/drain patterns SD1 to each other.

The first channel pattern CH1 may include a first semiconductor pattern SP1 and a second semiconductor pattern SP2, which are sequentially stacked. The first and second semiconductor patterns SP1 and SP2 may be spaced apart from each other in a vertical direction D3 that is perpendicular to a top surface of the substrate 100. In an embodiment, the first channel pattern CH1 may include three or more semiconductor patterns, which are spaced apart from each other in the vertical direction D3. The semiconductor patterns in the first channel pattern CH1 may be referred to as lower semiconductor patterns. A first direction D1 and a second direction D2 may be parallel to the top surface of the substrate 100 and may not be parallel to each other. A third direction D3 may be the vertical direction D3 perpendicular to the top surface of the substrate 100. The first direction D1, the second direction D2, and the third direction D3 may be orthogonal to each other.

Each of the first and second semiconductor patterns SP1 and SP2 may be formed of or include at least one of silicon (Si), germanium (Ge), or silicon germanium (SiGe). In an embodiment, each of the first and second semiconductor patterns SP1 and SP2 may be formed of or include crystalline silicon.

The first source/drain patterns SD1 may be disposed on a top surface of the lower insulating layer BDI. Each of the first source/drain patterns SD1 may be an epitaxial pattern, which is formed by a selective epitaxial growth (SEG) process. A top surface of the first source/drain pattern SD1 may be higher than a top surface of the second semiconductor pattern SP2 of the first channel pattern CH1. In this regard, the top surface of the first source/drain pattern SD1 may be higher than a top surface of the uppermost one of the lower semiconductor patterns of the first channel pattern CH1.

The first source/drain patterns SD1 may be doped to have a first conductivity type. The first conductivity type may be an n-type or a p-type. The first source/drain patterns SD1 may be formed of or include silicon (Si) and/or silicon germanium (SiGe).

A first interlayer insulating layer 110 may be disposed on the first source/drain patterns SD1. The first interlayer insulating layer 110 may cover the first source/drain patterns SD1. A second interlayer insulating layer 120 and the second active region AR2 may be disposed on the first interlayer insulating layer 110.

The second active region AR2 may include a second channel pattern CH2 and second source/drain patterns SD2, which are disposed at both (i.e., opposite) sides of the second channel pattern CH2. The second channel pattern CH2 may be vertically overlapped with the first channel pattern CH1. The second source/drain patterns SD2 may be vertically overlapped with the first source/drain patterns SD1, respectively. The second channel pattern CH2 may be interposed between the second source/drain patterns SD2. The second channel pattern CH2 may connect the second source/drain patterns SD2 to each other.

The second channel pattern CH2 may include a third semiconductor pattern SP3 and a fourth semiconductor pattern SP4, which are sequentially stacked. The third and fourth semiconductor patterns SP3 and SP4 may be spaced apart from each other in the vertical direction D3. In an embodiment, the second channel pattern CH2 may include three or more semiconductor patterns, which are spaced apart from each other in the vertical direction D3. The semiconductor patterns in the second channel pattern CH2 may be referred to as upper semiconductor patterns. Each of the upper semiconductor patterns may be formed of or include the same semiconductor material as the lower semiconductor patterns described above.

An intermediate insulating layer MDI may be interposed between the first channel pattern CH1 and the second channel pattern CH2. The intermediate insulating layer MDI may be spaced apart from the first source/drain patterns SD1. The intermediate insulating layer MDI may be spaced apart from the second source/drain patterns SD2. That is, the intermediate insulating layer MDI may not be connected to any one of the source/drain patterns. The intermediate insulating layer MDI may be formed of or include at least one of insulating materials (e.g., silicon oxide, silicon nitride, and/or silicon oxynitride).

The second source/drain patterns SD2 may be disposed on a top surface of the first interlayer insulating layer 110. Each of the second source/drain patterns SD2 may be an epitaxial pattern, which is formed by a SEG process. A top surface of the second source/drain pattern SD2 may be higher than a top surface of the fourth semiconductor pattern SP4 of the second channel pattern CH2. That is, the top surface of the second source/drain pattern SD2 may be higher than a top surface of the uppermost one of the upper semiconductor patterns of the second channel pattern CH2.

The second source/drain patterns SD2 may be doped to have a second conductivity type. The second conductivity type may be different from the first conductivity type of the first source/drain pattern SD1. The second source/drain patterns SD2 may be formed of or include silicon germanium (SiGe) and/or silicon (Si).

The second interlayer insulating layer 120 may cover the second source/drain patterns SD2. A top surface of the second interlayer insulating layer 120 may be coplanar with a top surface of each of first and second active contacts AC1 and AC2, which will be described below.

A gate electrode GE may be disposed on the first and second channel patterns CH1 and CH2. When viewed in a plan view, the gate electrode GE may be a line-shaped pattern that is extended in the first direction D1. The gate electrode GE may be vertically overlapped with the first and second channel patterns CH1 and CH2.

The gate electrode GE may include a first gate electrode GE1 that is interposed between the first source/drain patterns SD1. The first gate electrode GE1 may be vertically overlapped with the first channel patterns CH1. In detail, the first gate electrode GE1 may include a first portion PO1 disposed below the first semiconductor pattern SP1, a second portion PO2 interposed between the first semiconductor pattern SP1 and the second semiconductor pattern SP2, and a third portion PO3 disposed on the second semiconductor pattern SP2. The third portion PO3 may be interposed between the second semiconductor pattern SP2 and the intermediate insulating layer MDI. In an embodiment, the first gate electrode GE1 may include lower inner electrodes and the lowermost electrode. The lower inner electrodes may include a plurality of lower inner electrodes which are interposed between the lower semiconductor patterns. The lowermost electrode may be interposed between the lowermost one of the lower semiconductor patterns and the lower insulating layer BDI.

The gate electrode GE may include a second gate electrode GE2 interposed between the second source/drain patterns SD2. The second gate electrode GE2 may be vertically overlapped with the second channel pattern CH2. In detail, the second gate electrode GE2 may include a fourth portion PO4 disposed below the third semiconductor pattern SP3, a fifth portion PO5 interposed between the third semiconductor pattern SP3 and the fourth semiconductor pattern SP4, and a sixth portion PO6 disposed on the fourth semiconductor pattern SP4. The fourth portion PO4 may be interposed between the intermediate insulating layer MDI and the third semiconductor pattern SP3. In an embodiment, the second gate electrode GE2 may include upper inner electrodes and the uppermost electrode. The upper inner electrodes may include a plurality of upper inner electrodes interposed between the upper semiconductor patterns. The uppermost electrode may be disposed on the uppermost one of the upper semiconductor patterns.

The first gate electrode GE1 may be disposed in the first active region AR1. The second gate electrode GE2 may be disposed in the second active region AR2. The first and second gate electrodes GE1 and GE2 may be vertically overlapped with each other.

The gate electrode GE may include an outer gate electrode OGE. The outer gate electrode OGE may extend from the top surface of the device isolation layer ST in the vertical direction D3. The outer gate electrode OGE may connect the first and second gate electrodes GE1 and GE2 to each other.

The first gate electrode GE1 may include a first work-function metal pattern. The second gate electrode GE2 may include a second work-function metal pattern. Each of the first and second work-function metal patterns may be formed of a material, which contains at least one metallic element, which is selected from the group consisting of titanium (Ti), tantalum (Ta), aluminum (Al), tungsten (W), and molybdenum (Mo), and nitrogen (N). The first and second work-function metal patterns may have different work functions from each other. The outer gate electrode OGE may include at least one of low resistance metals (e.g., tungsten (W), ruthenium (Ru), aluminum (Al), titanium (Ti), and tantalum (Ta)).

The gate electrode GE may be disposed on a top surface, a bottom surface, and opposite side surfaces of each of the first and second channel patterns CH1 and CH2. That is, the transistor according to the present embodiment may include a three-dimensional field effect transistor (e.g., multi-bridge channel FET (MBCFET) or gate-all-around FETs (GAAFET)) in which the gate electrode GE is provided to three-dimensionally surround the channel pattern.

A first ferroelectric pattern FE1 may be interposed between the substrate 100 and the first channel pattern CH1. In detail, the first ferroelectric pattern FE1 may be interposed between the lower insulating layer BDI of the substrate 100 and the first semiconductor pattern SP1 of the first channel pattern CH1. The first ferroelectric pattern FE1 may be interposed between the first source/drain patterns SD1. The first portion PO1 of the first gate electrode GE1 may be interposed between the first semiconductor pattern SP1 and the first ferroelectric pattern FE1. In an embodiment, the first ferroelectric pattern FE1 may be interposed between the lowermost one of the lower semiconductor patterns of the first channel pattern CH1 and the lower insulating layer BDI. The first ferroelectric pattern FE1 may be interposed between the lowermost electrode of the first gate electrode GE1 and the lower insulating layer BDI. The lowermost electrode of the first gate electrode GE1 may be interposed between the lowermost one of the lower semiconductor patterns and the lower insulating layer BDI.

A second ferroelectric pattern FE2 may be disposed on the second channel pattern CH2. In detail, the second ferroelectric pattern FE2 may be interposed between the fourth semiconductor pattern SP4 of the second channel pattern CH2 and the outer gate electrode OGE. The second ferroelectric pattern FE2 may be interposed between the second source/drain patterns SD2. The sixth portion PO6 of the second gate electrode GE2 may be interposed between the second ferroelectric pattern FE2 and the fourth semiconductor pattern SP4. In an embodiment, the second ferroelectric pattern FE2 may be interposed between the uppermost one of the upper semiconductor patterns of the second channel pattern CH2 and the outer gate electrode OGE. The second ferroelectric pattern FE2 may be interposed between the uppermost one of the second gate electrode GE2 and the outer gate electrode OGE. The uppermost one of the second gate electrodes GE2 may be interposed between the uppermost one of the upper semiconductor patterns and the second ferroelectric pattern FE2.

The first and second ferroelectric patterns FE1 and FE2 may include hafnium oxide, which contains (or is doped) with at least one of zirconium (Zr), silicon (Si), aluminum (Al), or lanthanum (La).

A pair of gate spacers GS may be disposed on opposite side surfaces of the gate electrode GE, respectively. Referring to FIG. 2A, the gate spacers GS may be disposed on opposite side surfaces of the outer gate electrode OGE, respectively, which is placed on the second ferroelectric pattern FE2. The gate spacers GS may extend along the gate electrode GE and in the first direction D1. Top surfaces of the gate spacers GS may be higher than a top surface of the gate electrode GE. The top surfaces of the gate spacers GS may be coplanar with the top surface of the second interlayer insulating layer 120. The gate spacers GS may be formed of or include at least one of SiCN, SiCON, or SiN. In an embodiment, the gate spacers GS may have a multi-layered structure, which includes at least two different materials selected from SiCN, SiCON, and SiN. A pair of liner layers LIN may be respectively provided on opposite side surfaces of each of the third portion PO3 of the first gate electrode GE1 and the fourth portion PO4 of the second gate electrode GE2.

A gate capping pattern GP may be provided on the top surface of the gate electrode GE. The gate capping pattern GP may extend along the gate electrode GE or in the first direction D1. In an embodiment, the gate capping pattern GP may be formed of or include at least one of SiON, SiCN, SiCON, or SiN.

A gate insulating layer GI may be interposed between each of the first and second channel patterns CH1 and CH2 and the gate electrode GE. The gate insulating layer GI may include a silicon oxide layer, a silicon oxynitride layer, and/or a high-k dielectric layer. In this regard, the gate insulating layer GI may have a multi-layered structure including the silicon oxide layer and the high-k dielectric layer.

The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

A gate contact GC may be provided to penetrate a third interlayer insulating layer 130 and the gate capping pattern GP and may be electrically connected to the gate electrode GE. The gate contact GC may be formed of or include at least one of metallic materials selected from the group consisting of copper (Cu), aluminum (Al), ruthenium (Ru), cobalt (Co), tungsten (W), and molybdenum (Mo).

Active contacts AC1 to AC4 may be disposed to be electrically connected to the first and second source/drain patterns SD1 and SD2. In detail, referring to FIG. 1, a first active contact AC1 and a third active contact AC3 may be disposed to face a side surface of the gate electrode GE. A second active contact AC2 and a fourth active contact AC4 may be formed to face an opposite side surface of the gate electrode GE. For example, each of the first to fourth active contacts AC1 to AC4 may be formed of or include a doped semiconductor material and/or a metallic material. For example, the metallic material may be selected from the group consisting of copper (Cu), aluminum (Al), ruthenium (Ru), cobalt (Co), tungsten (W), and molybdenum (Mo).

The first to fourth active contacts AC1 to AC4 may extend from the top surface of the second interlayer insulating layer 120 to the first source/drain patterns SD1 through the second source/drain patterns SD2. In an embodiment, the first to fourth active contacts AC1 to AC4 may have bottom surfaces that are located at the same level. In this regard, the first to fourth active contacts AC1 to AC4 may be formed to have substantially the same depth.

Referring to FIGS. 1 and 2C, the first and third active contacts AC1 and AC3 may be provided to penetrate both of the first and second source/drain patterns SD1 and SD2 which are stacked. The first and third active contacts AC1 and AC3 may be respectively disposed at both (i.e., opposite) sides of the first source/drain pattern SD1. The first and third active contacts AC1 and AC3 may be respectively disposed at both (i.e., opposite) sides of the second source/drain pattern SD2.

The first active contact AC1 may be electrically connected to the first source/drain pattern SD1, but not to the second source/drain pattern SD2. The third active contact AC3 may be electrically connected to the second source/drain pattern SD2, but not to the first source/drain pattern SD1.

In detail, an upper separation structure USS may be interposed between the first active contact AC1 and the second source/drain pattern SD2. The upper separation structure USS may cover a side surface of the first active contact AC1. Due to the upper separation structure USS, the first active contact AC1 may not be in contact with, or may be spaced apart from, the second source/drain pattern SD2. In this regard, the upper separation structure USS may electrically isolate the first active contact AC1 from the second source/drain pattern SD2. The first active contact AC1 may be coupled to the first source/drain pattern SD1.

A lower separation structure LSS may be interposed between the third active contact AC3 and the first source/drain pattern SD1. The lower separation structure LSS may cover side and bottom surfaces of the third active contact AC3. Due to the lower separation structure LSS, the third active contact AC3 may not be in contact with, or may be spaced apart from, the first source/drain pattern SD1. In this regard, the lower separation structure LSS may electrically isolate the third active contact AC3 from the first source/drain pattern SD1. The third active contact AC3 may be coupled to the second source/drain pattern SD2.

Referring back to FIGS. 1 and 2A to 2D, the second and fourth active contacts AC2 and AC4 may be provided to penetrate both of the first and second source/drain patterns SD1 and SD2 which are stacked. Due to the upper separation structure USS, the second active contact AC2 may be electrically connected to the first source/drain pattern SD1, but not to the second source/drain pattern SD2. In this regard, the upper separation structure USS may electrically isolate the second active contact AC2 from the second source/drain pattern SD2. Due to the lower separation structure LSS, the fourth active contact AC4 may be electrically connected to the second source/drain pattern SD2, but not to the first source/drain pattern SD1. In this regard, the lower separation structure LSS may electrically isolate the fourth active contact AC4 from the first source/drain pattern SD1.

According to an embodiment, the first to fourth active contacts AC1 to AC4, which are two-dimensionally arranged, may be respectively coupled to four source/drain terminals stacked. For example, the first active contact AC1 may be coupled to a lower source terminal, the third active contact AC3 may be coupled to an upper source terminal, the second active contact AC2 may be coupled to a lower drain terminal, and the fourth active contact AC4 may be coupled to an upper drain terminal.

The third interlayer insulating layer 130 may be provided on the second interlayer insulating layer 120. A fourth interlayer insulating layer 140 may be provided on the third interlayer insulating layer 130. In an embodiment, connection lines CNL may be provided in the third interlayer insulating layer 130. The connection lines CNL may be provided on the first to fourth active contacts AC1 to AC4, respectively.

A first metal layer M1 may be provided in the fourth interlayer insulating layer 140. The first metal layer M1 may include the first to third interconnection lines MI1, MI2, and MI3, which are sequentially arranged in the first direction D1. The first to third interconnection lines MI1, MI2, and MI3 may extend in the second direction D2 to be parallel to each other. The first to third interconnection lines MI1, MI2, and MI3 may be formed of or include at least one of metallic materials (e.g., copper (Cu), aluminum (Al), ruthenium (Ru), cobalt (Co), tungsten (W), and molybdenum (Mo)).

The first metal layer M1 may further include vias VI, which are provided in lower elements thereof. At least one of the first to third interconnection lines MI1, MI2, and MI3 may be electrically connected to at least one of the first to fourth active contacts AC1 to AC4 through the via VI and the connection line CNL. Another one of the first to third interconnection lines MI1, MI2, and MI3 may be electrically connected to the gate contact GC through the via VI.

Additional metal layers (e.g., M2, M3, M4, and so forth) may be stacked on the first metal layer M1. The first metal layer M1 and the additional metal layers (e.g., M2, M3, M4, and so forth) thereon may constitute a back-end-of-line (BEOL) layer of the semiconductor device.

A negative capacitance field effect transistor (NCFET) may be a transistor, which includes a ferroelectric material between a gate electrode and a dielectric layer, and consequently may have an improved sub-threshold swing property and a lowered operation voltage. For example, when an external voltage is applied to a ferroelectric pattern, the dipoles in the ferroelectric pattern may move, and in this case, a negative capacitance effect may occur, where the initial polarization state of the ferroelectric pattern changes to a different polarization state. In this case, a total capacitance of the transistor including the ferroelectric material may be increased, and this may make it possible to improve the sub-threshold swing characteristics of the transistor and lower the operation voltage of the transistor. However, for a related 3-dimensional stacked field effect transistor (3DSFET) structure, a space for the ferroelectric material may be limited in a lower transistor.

According to an embodiment, by virtue of a process of forming a 3DSFET structure to be described below, the lower transistor may be fabricated to include the first ferroelectric pattern FE1. Thus, the lower transistor may be fabricated to have the NCFET structure. In an embodiment, depending on a position of the ferroelectric material, the NCFET structure may have a metal-ferroelectric-semiconductor (MFS) structure, a metal-ferroelectric-insulator-semiconductor (MFIS) structure, and a metal-ferroelectric-metal-insulator-semiconductor (MFMIS) structure. In an embodiment consistent with FIGS. 2A to 2D, the lower transistor may have the MFMIS structure, which includes the outer gate electrode OGE, the first ferroelectric pattern FE1, the first gate electrode GE1, the gate insulating layer GI, and the first channel pattern CH1. Thus, it may be possible to prevent an interfacial property between the silicon and the ferroelectric material and the polarization property of the ferroelectric material from being deteriorated and thereby to improve the electrical characteristics of the three-dimensional semiconductor device.

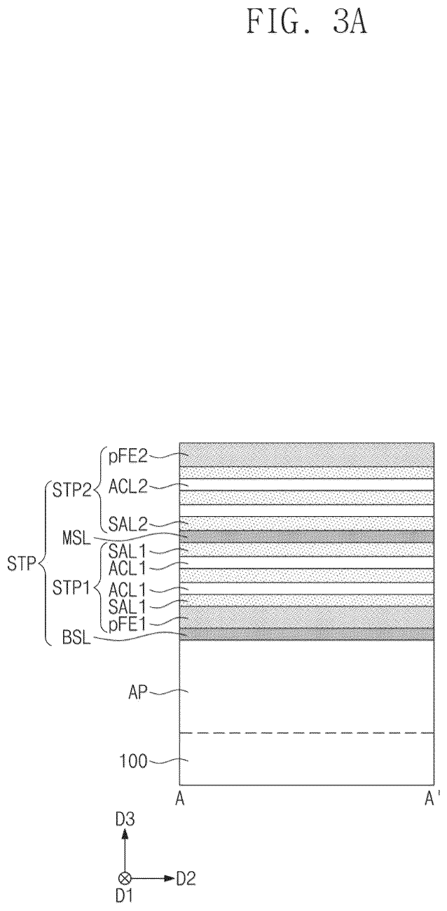

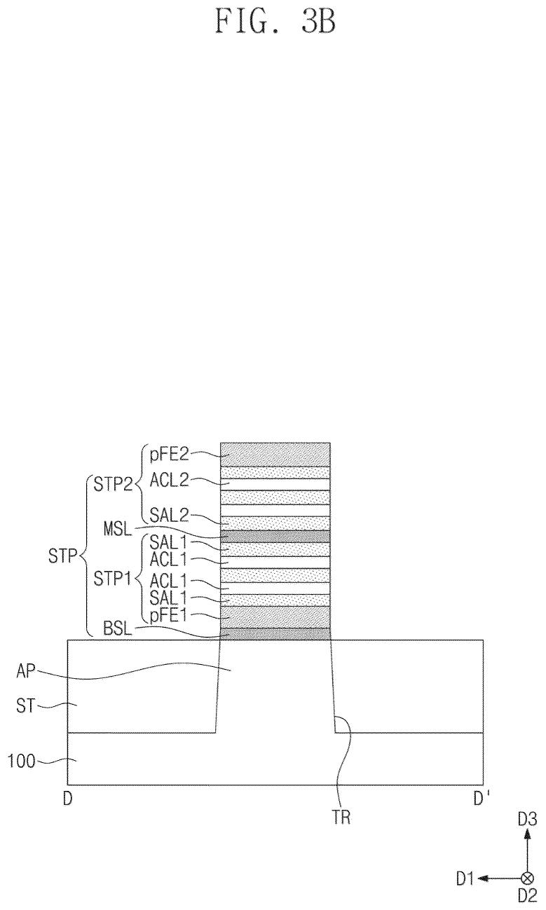

FIGS. 3A to 16B are sectional views illustrating a method of fabricating a semiconductor device according to an embodiment. For concise description, a previously described element may be identified by the same reference number without repeating an overlapping description thereof.

Referring to FIGS. 3A and 3B, a lower sacrificial layer BSL may be formed on the substrate 100. A preliminary first ferroelectric layer pFE1 may be formed on the lower sacrificial layer BSL. First sacrificial layers SAL1 and first active layers ACL1 may be alternatively stacked on the preliminary first ferroelectric layer pFE1. The lower sacrificial layer BSL, the preliminary first ferroelectric layer pFE1, and the first sacrificial layers SAL1 may be formed of or include one of silicon (Si), germanium (Ge), and silicon germanium (SiGe), and the first active layers ACL1 may be formed of or include one of silicon (Si), germanium (Ge), and silicon germanium (SiGe) and may be formed of a different material from the lower sacrificial layer BSL, the preliminary first ferroelectric layer pFE1, and the first sacrificial layers SAL1. For example, the lower sacrificial layer BSL, the preliminary first ferroelectric layer pFE1, and the first sacrificial layers SAL1 may be formed of or include silicon germanium (SiGe), and the first active layers ACL1 may be formed of or include silicon (Si). The germanium concentration of the lower sacrificial layer BSL may range from 45 at % to 55 at %. In an embodiment, the germanium concentration of the lower sacrificial layer BSL may be 50 at %. The germanium concentration of the preliminary first ferroelectric layer pFE1 may range from 30 at % to 40 at %. In an embodiment, the germanium concentration of the preliminary first ferroelectric layer pFE1 may be 35 at %. The germanium concentration of each of the first sacrificial layers SAL1 may range from 15 at % to 25 at %. In an embodiment, the germanium concentration of each of the first sacrificial layers SAL1 may be 20 at %.

An intermediate sacrificial layer MSL may be formed on the uppermost one of the first active layers ACL1. The intermediate sacrificial layer MSL may be formed of or include silicon (Si) or silicon germanium (SiGe). In the case where the intermediate sacrificial layer MSL includes silicon germanium (SiGe), the germanium concentration of the intermediate sacrificial layer MSL may range from 45 at % to 55 at %. In an embodiment, the germanium concentration of the intermediate sacrificial layer MSL may be 50 at %.

Second sacrificial layers SAL2 and second active layers ACL2 may be alternatively stacked on the intermediate sacrificial layer MSL. Each of the second sacrificial layers SAL2 may be formed of or include the same material as the first sacrificial layer SAL1, and each of the second active layers ACL2 may be formed of or include the same material as the first active layer ACL1. The intermediate sacrificial layer MSL may be interposed between the first sacrificial layer SAL1 and the second sacrificial layer SAL2. A preliminary second ferroelectric layer pFE2 may be formed on the uppermost one of the second active layers ACL2. The preliminary second ferroelectric layer pFE2 may be formed of or include at least one of silicon (Si), germanium (Ge), or silicon germanium (SiGe). For example, in the case where the preliminary second ferroelectric layer pFE2 includes silicon germanium (SiGe), the germanium concentration of the preliminary second ferroelectric layer pFE2 may range from 30 at % to 40 at %. In an embodiment, the germanium concentration of the preliminary second ferroelectric layer pFE2 may be 35 at %.

A stacking pattern STP may be formed by patterning the lower sacrificial layer BSL, the preliminary first ferroelectric layer pFE1, the first and second sacrificial layers SAL1 and SAL2, the intermediate sacrificial layer MSL, the first and second active layers ACL1 and ACL2, and the preliminary second ferroelectric layer pFE2 stacked. The formation of the stacking pattern STP may include forming a hard mask pattern on the preliminary second ferroelectric layer pFE2 and sequentially etching the layers BSL, pFE1, SAL1, ACL1, MSL, SAL2, ACL2, and pFE2, which are stacked on the substrate 100, using the hard mask pattern as an etch mask. During the formation of the stacking pattern STP, an upper portion of the substrate 100 may be patterned to form the trench TR defining the active pattern AP. The stacking pattern STP may be a bar-shaped pattern that is extended in the second direction D2.

The stacking pattern STP may include a lower stacking pattern STP1 on the active pattern AP, an upper stacking pattern STP2 on the lower stacking pattern STP1, a lower sacrificial layer BSL between the active pattern AP and the lower stacking pattern STP1, and an intermediate sacrificial layer MSL between the lower and upper stacking patterns STP1 and STP2. The lower stacking pattern STP1 may include the first sacrificial layers SAL1 and the first active layers ACL1, which are alternately stacked. The upper stacking pattern STP2 may include the second sacrificial layers SAL2 and the second active layers ACL2, which are alternately stacked.

The device isolation layer ST may be formed on the substrate 100 to fill the trench TR. In detail, an insulating layer may be formed on the substrate 100 to cover the active pattern AP and the stacking pattern STP. The device isolation layer ST may be formed by recessing the insulating layer until the stacking pattern STP is exposed.

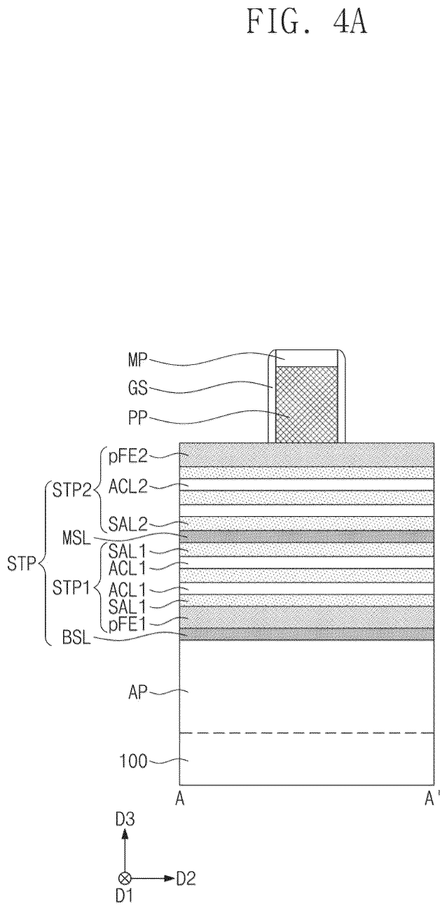

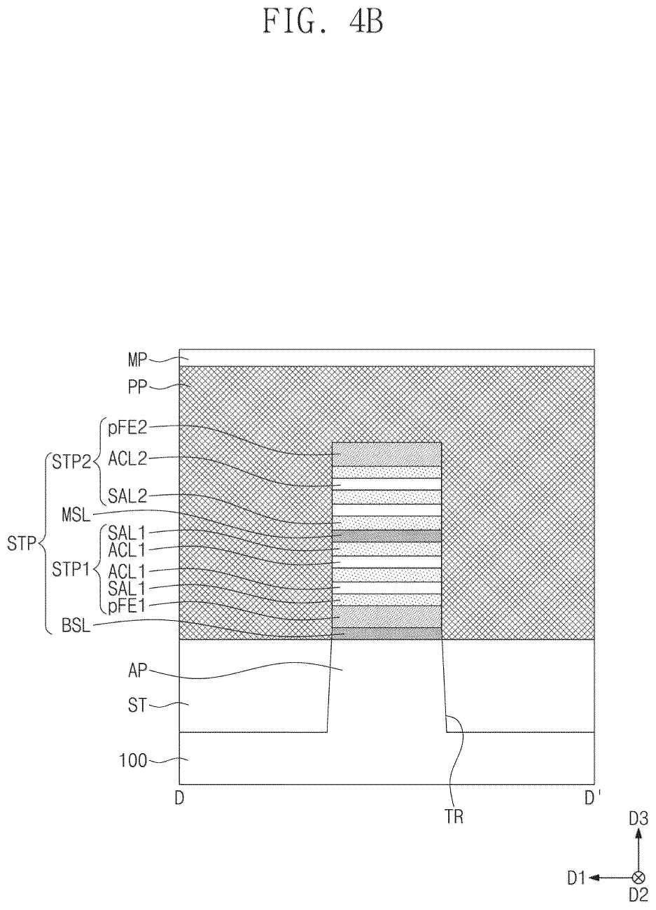

Referring to FIGS. 4A and 4B, a sacrificial pattern PP may be formed to cross the stacking pattern STP. The sacrificial pattern PP may be formed to have a line shape extending in the first direction D1. In detail, the formation of the sacrificial pattern PP may include forming a sacrificial layer on the substrate 100, forming a hard mask pattern MP on the sacrificial layer, and patterning the sacrificial layer using the hard mask pattern MP as an etch mask. The sacrificial layer may be formed of or include amorphous silicon and/or polysilicon.

A pair of the gate spacers GS may be respectively formed on opposite side surfaces of the sacrificial pattern PP. In detail, a spacer layer may be conformally formed on the substrate 100. The spacer layer may cover the sacrificial pattern PP and the hard mask pattern MP. For example, the spacer layer may be formed of or include at least one of SiCN, SiCON, or SiN. The gate spacers GS may be formed by anisotropically etching the spacer layer.

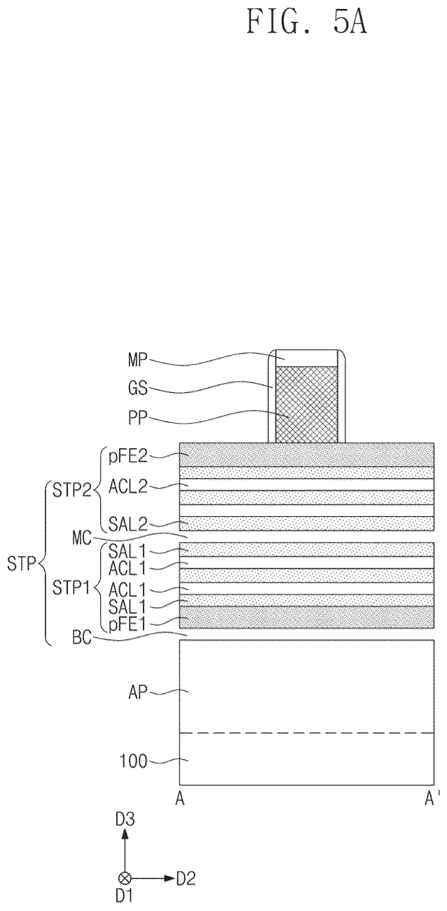

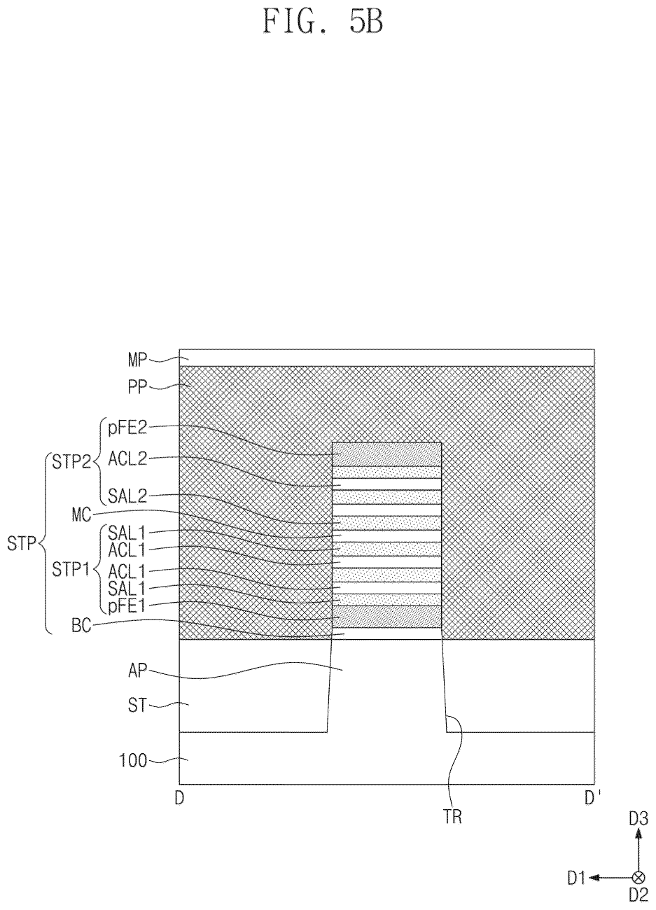

Referring to FIGS. 5A and 5B, a lower cavity BC and an intermediate cavity MC may be formed. The lower cavity BC and the intermediate cavity MC may be formed through a first etching process that is performed to selectively remove the lower sacrificial layer BSL and the intermediate sacrificial layer MSL. The first etching process may be performed to etch a silicon germanium (SiGe) layer, which has a relatively high germanium concentration, at a high etch rate. For example, the first etching process may be performed to selectively remove a silicon germanium (SiGe) layer whose germanium concentration ranges from 45 at % to 55 at %. A silicon germanium (SiGe) layer with a relatively low germanium concentration may not be etched by the first etching process. Thus, the first and second sacrificial layers SAL1 and SAL2 and the preliminary first and second ferroelectric layers pFE1 and pFE2 may be left, after the first etching process.

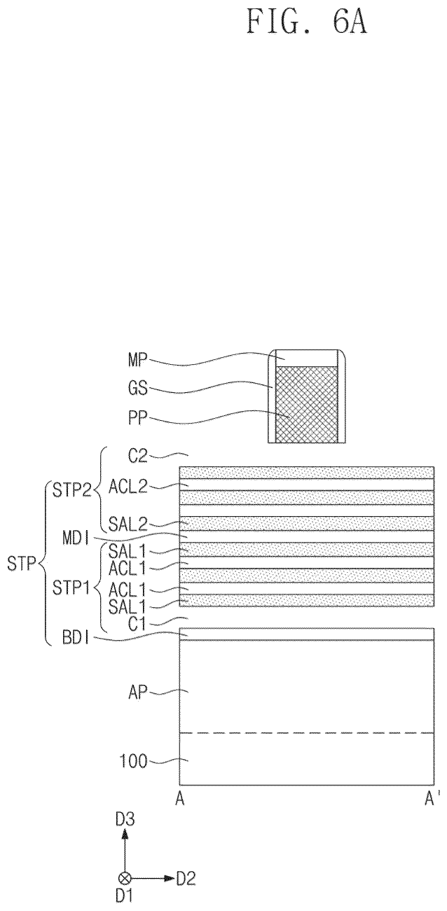

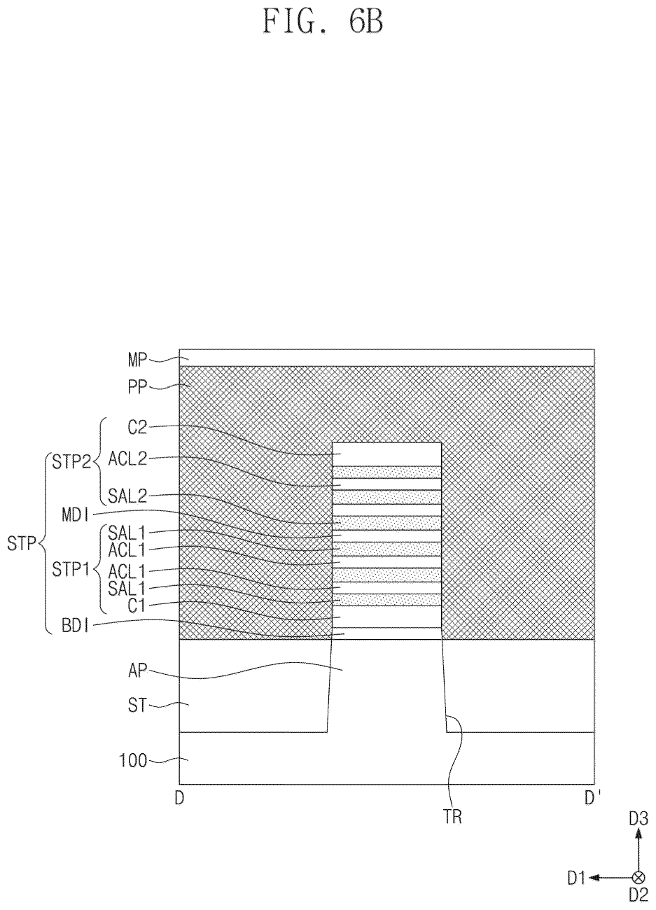

Referring to FIGS. 6A and 6B, the lower and intermediate insulating layers BDI and MDI may be formed. In an embodiment, the lower and intermediate insulating layers BDI and MDI may be formed by filling the lower cavity BC and the intermediate cavity MC with an insulating material.

Thereafter, a first cavity C1 and a second cavity C2 may be formed. The formation of the first and second cavities C1 and C2 may be formed through a second etching process of selectively etching the preliminary first and second ferroelectric layers pFE1 and pFE2. The second etching process may be performed to etch a silicon germanium (SiGe) layer, which has a relatively intermediate germanium concentration, at a high etch rate. For example, the second etching process may be performed to selectively remove a silicon germanium (SiGe) layer whose germanium concentration ranges from 30 at % to 40 at %. A silicon germanium (SiGe) layer having a relatively low germanium concentration may not be etched by the second etching process. Thus, the first and second sacrificial layers SAL1 and SAL2 may be left, after the second etching process.

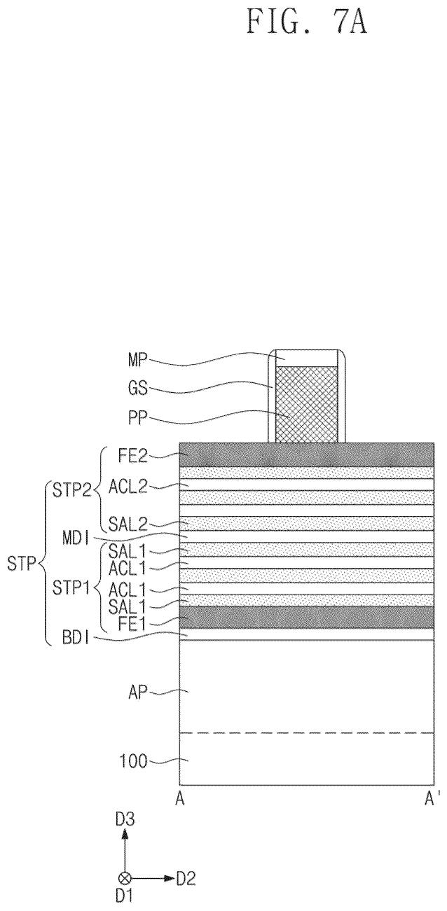

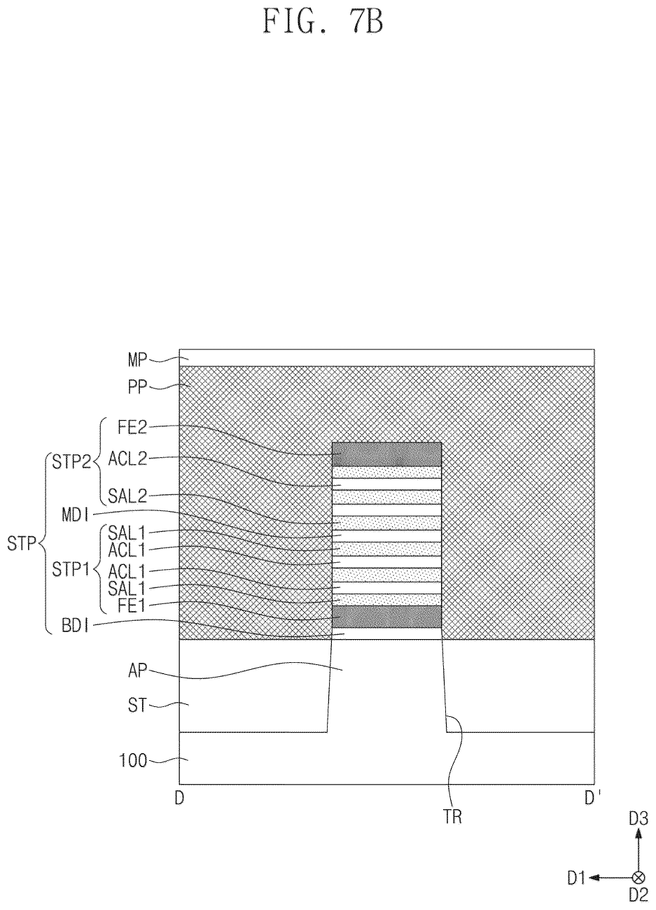

Referring to FIGS. 7A and 7B, the first and second ferroelectric patterns FE1 and FE2 may be formed. The first and second ferroelectric patterns FE1 and FE2 may be formed through a process of filling the first and second cavities C1 and C2 with a ferroelectric material.

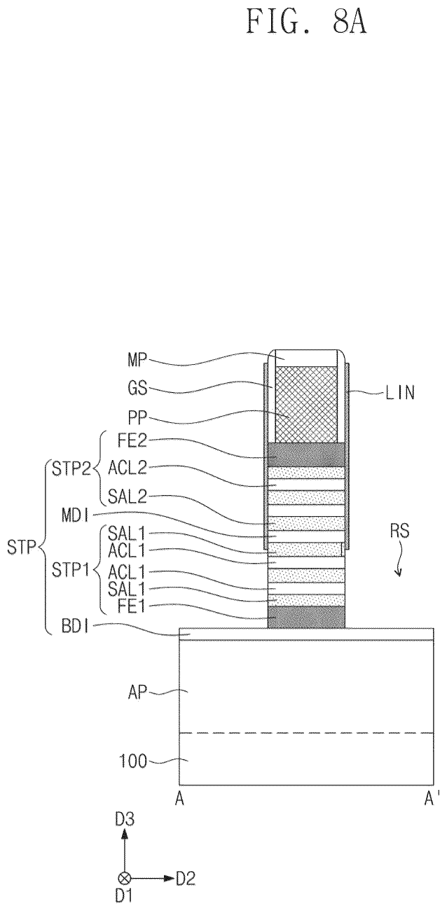

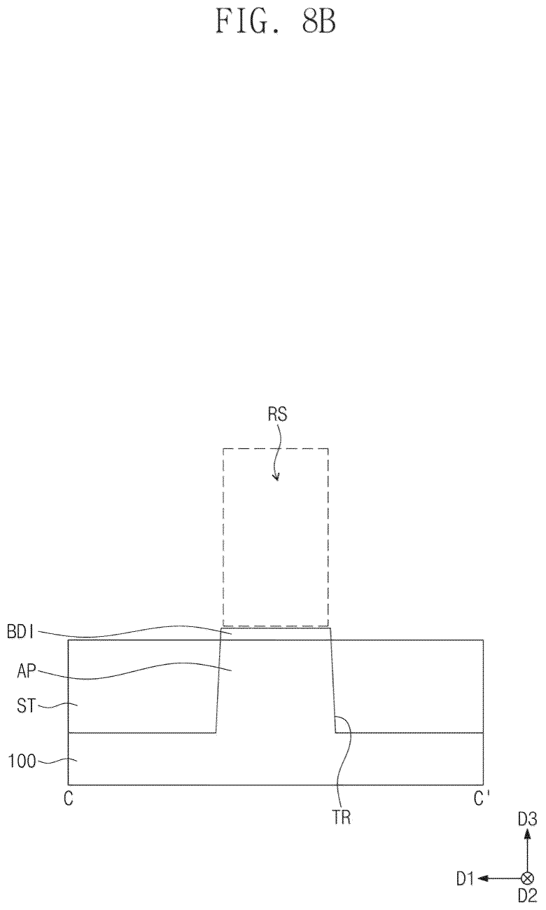

Referring to FIGS. 8A and 8B, an etching process may be performed on the stacking pattern STP using the gate spacers GS and the hard mask pattern MP as an etch mask. A pair of recesses RS may be formed at both (i.e., opposite) sides of the sacrificial pattern PP by the etching process.

The liner layers LIN may be respectively formed on opposite side surfaces of the upper stacking pattern STP2. The liner layers LIN may prevent the upper stacking pattern STP2 from being exposed to the recesses RS. The liner layers LIN may be formed to expose the lower stacking pattern STP1. In an embodiment, the liner layers LIN may be formed of or include silicon nitride.

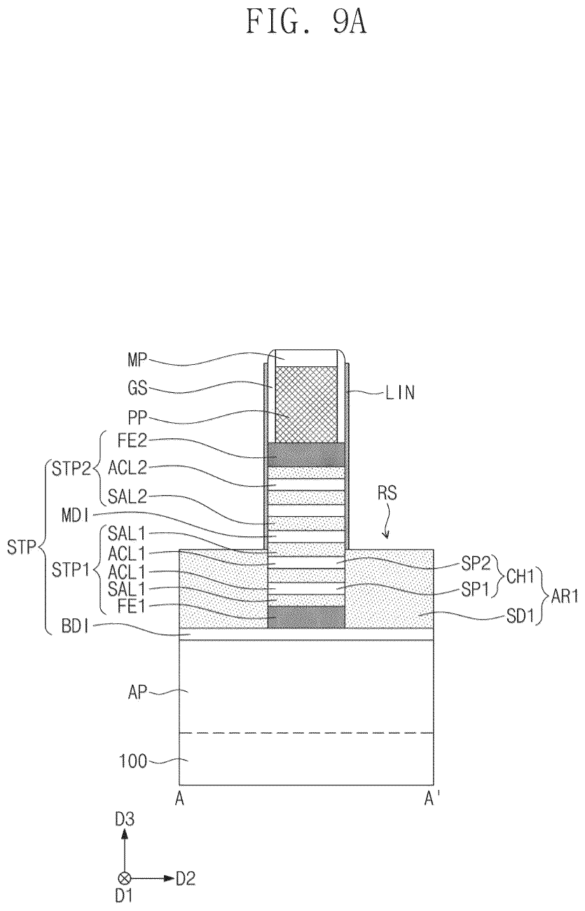

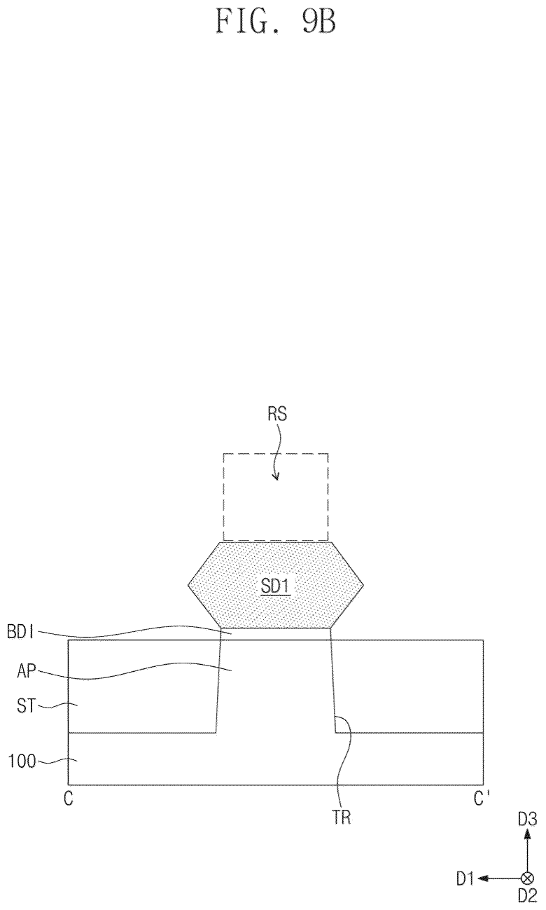

Referring to FIGS. 9A and 9B, the first source/drain patterns SD1 may be formed in the recesses RS, respectively. In detail, a first SEG process using a side surface of the exposed lower stacking pattern STP1 as a seed layer may be performed to form the first source/drain pattern SD1. The first source/drain pattern SD1 may be grown using the first active layers ACL1, which are exposed by the recess RS, as the seed layer. In an embodiment, the first SEG process may include a chemical vapor deposition (CVD) process or a molecular beam epitaxy (MBE) process. The first source/drain patterns SD1 may cover side surfaces of the first ferroelectric pattern FE1. Bottom surfaces of the first source/drain patterns SD1 may be coplanar with a bottom surface of the first ferroelectric pattern FE1.

During the first SEG process, impurities may be injected in-situ into the first source/drain pattern SD1. Alternatively, impurities may be injected into the first source/drain pattern SD1, after the formation of the first source/drain pattern SD1. The first source/drain pattern SD1 may be doped to have the first conductivity type (e.g., n type).

The first active layers ACL1, which are interposed between a pair of the first source/drain patterns SD1, may constitute the first channel pattern CH1. For example, the first and second semiconductor patterns SP1 and SP2 of the first channel pattern CH1 may be formed from the first active layers ACL1. The first channel pattern CH1 and the first source/drain patterns SD1 may constitute the first active region AR1, which is a lower tier of the three-dimensional semiconductor device.

Side surfaces of the upper stacking pattern STP2 may be covered with the liner layer LIN. That is, during the first SEG process, the second active layers ACL2 of the upper stacking pattern STP2 may not be exposed to the outside, due to the liner layer LIN. Thus, during the first SEG process, an additional semiconductor layer may not be grown on the upper stacking pattern STP2.

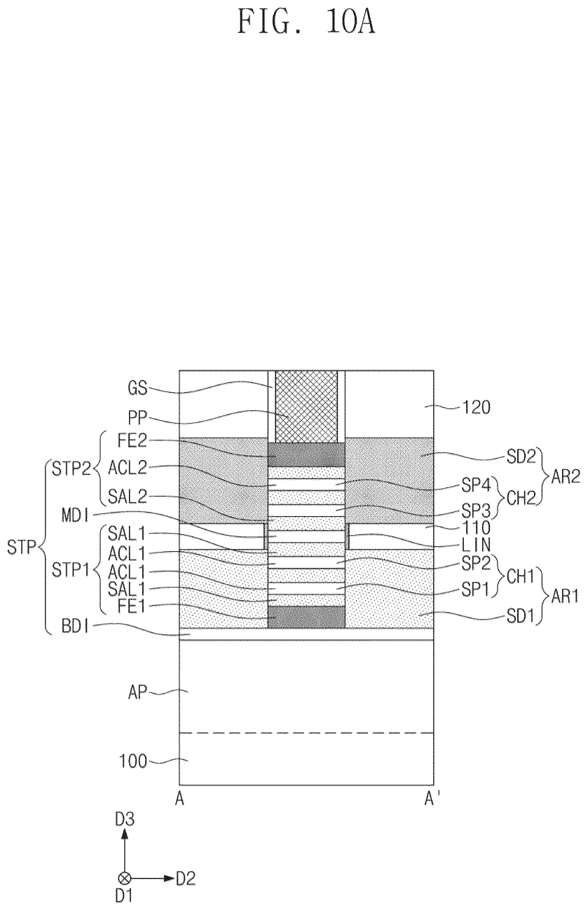

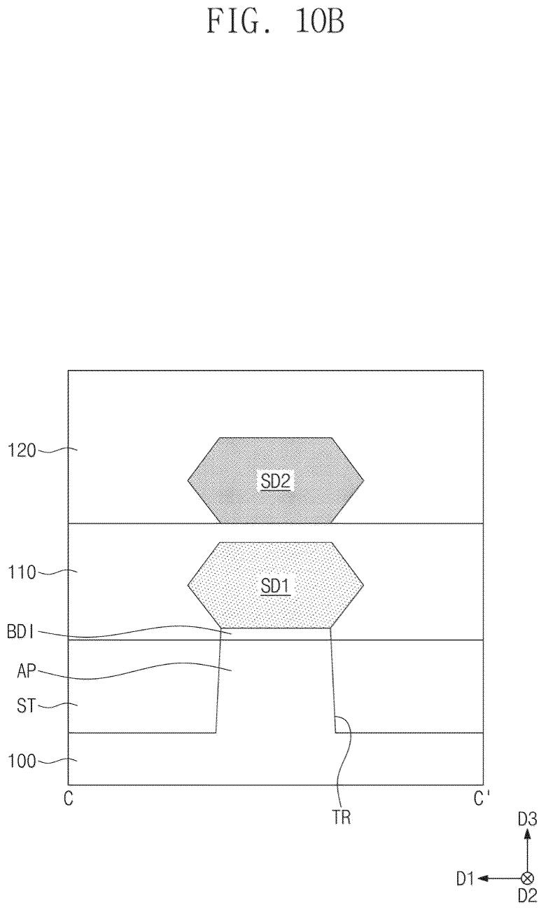

Referring to FIGS. 10A and 10B, the first interlayer insulating layer 110 may be formed to cover the first source/drain patterns SD1. The first interlayer insulating layer 110 may be recessed to have a top surface that is lower than a bottom surface of the lowermost one of the second active layers ACL2.

A portion of the liner layer LIN, which is exposed by the recess RS, may be removed. Another portion of the liner layer LIN, which is covered with the first interlayer insulating layer 110, may be left to cover a side surface of the intermediate insulating layer MDI. As a result of the partial removal of the liner layer LIN, the second active layers ACL2 may be exposed to the recess RS.

The second source/drain patterns SD2 may be respectively formed on the opposite side surfaces of the upper stacking pattern STP2. In detail, a second SEG process using the side surfaces of the upper stacking pattern STP2 as a seed layer may be performed to form the second source/drain pattern SD2. The second source/drain pattern SD2 may be grown using the second active layers ACL2, which are exposed to the recess RS, as the seed layer. The second source/drain patterns SD2 may cover side surfaces of the second ferroelectric pattern FE2. Top surfaces of the second source/drain patterns SD2 may be located at a level higher than a top surface of the second ferroelectric pattern FE2. The second source/drain patterns SD2 may be doped to have a second conductivity type (e.g., p type) that is different from the first conductivity type.

The second active layers ACL2, which are interposed between a pair of the second source/drain patterns SD2, may constitute the second channel pattern CH2. For example, the third and fourth semiconductor patterns SP3 and SP4 of the second channel pattern CH2 may be formed from the second active layers ACL2. The second channel pattern CH2 and the second source/drain patterns SD2 may constitute the second active region AR2, which is an upper tier of the three-dimensional semiconductor device.

The second interlayer insulating layer 120 may be formed to cover the hard mask pattern MP, the gate spacers GS, and the second source/drain patterns SD2. In an embodiment, the second interlayer insulating layer 120 may include a silicon oxide layer.

The second interlayer insulating layer 120 may be planarized to expose a top surface of the sacrificial pattern PP. The planarization of the second interlayer insulating layer 120 may be performed using an etch-back process or a chemical mechanical polishing (CMP) process. The hard mask pattern MP may be fully removed by the planarization process. As a result, a top surface of the second interlayer insulating layer 120 may be coplanar with the top surface of the sacrificial pattern PP and the top surfaces of the gate spacers GS.

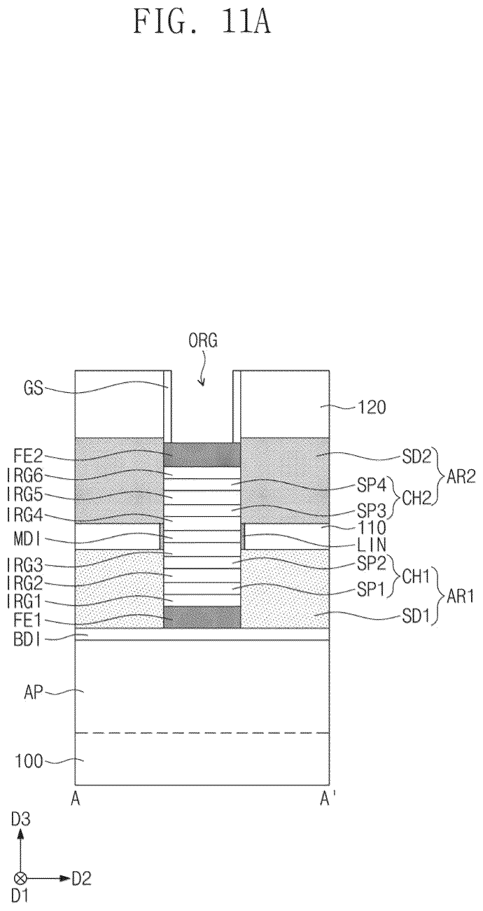

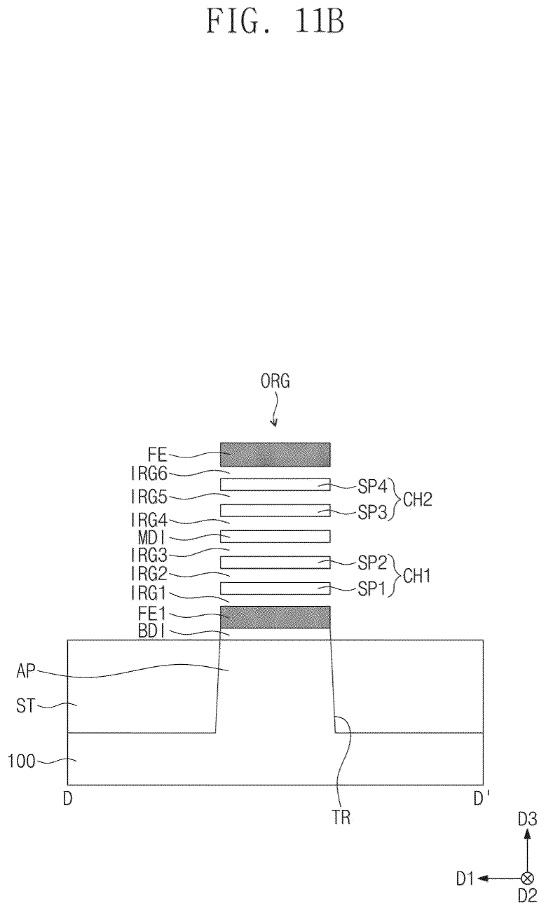

Referring to FIGS. 11A and 11B, the sacrificial pattern PP may be selectively removed. An outer region ORG exposing the first and second channel patterns CH1 and CH2 may be formed, as a result of the removal of the sacrificial pattern PP (e.g., see FIG. 11B). The removal of the sacrificial pattern PP may include a wet etching process using etching solution capable of selectively etching polysilicon.

The first and second sacrificial layers SAL1 and SAL2 exposed through the outer region ORG may be selectively removed to form first to sixth inner regions IRG1 to IRG6 (e.g., see FIG. 11B). In detail, a third etching process may be performed to selectively remove the first and second sacrificial layers SAL1 and SAL2, and to leave the first to fourth semiconductor patterns SP1 to SP4, the lower insulating layer BDI, the first ferroelectric pattern FE1, the intermediate insulating layer MDI, and the second ferroelectric pattern FE2.

As a result of the selective removal of the first and second sacrificial layers SAL1 and SAL2, the first and second semiconductor patterns SP1 and SP2 may be left on the first active region AR1, and the third and fourth semiconductor patterns SP3 and SP4 may be left on the second active region AR2.

An empty space between the first ferroelectric pattern FE1 and the first semiconductor pattern SP1 may be referred to as a first inner region IRG1, an empty space between the first semiconductor pattern SP1 and the second semiconductor pattern SP2 may be referred to as a second inner region IRG2, an empty space between the second semiconductor pattern SP2 and the intermediate insulating layer MDI may be referred to as a third inner region IRG3, an empty space between the intermediate insulating layer MDI and the third semiconductor pattern SP3 may be referred to as a fourth inner region IRG4, an empty space between the third semiconductor pattern SP3 and the fourth semiconductor pattern SP4 may be referred to as a fifth inner region IRG5, and an empty space between the fourth semiconductor pattern SP4 and the second ferroelectric pattern FE2 may be referred to as a sixth inner region IRG6.

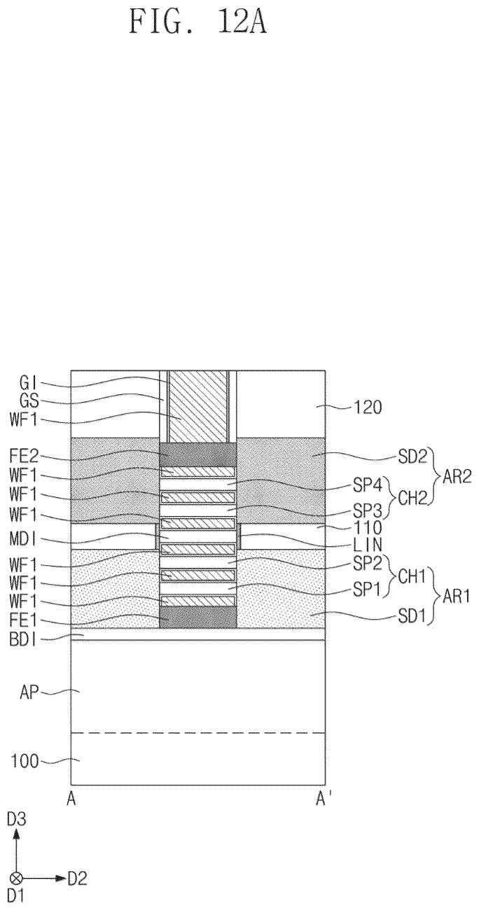

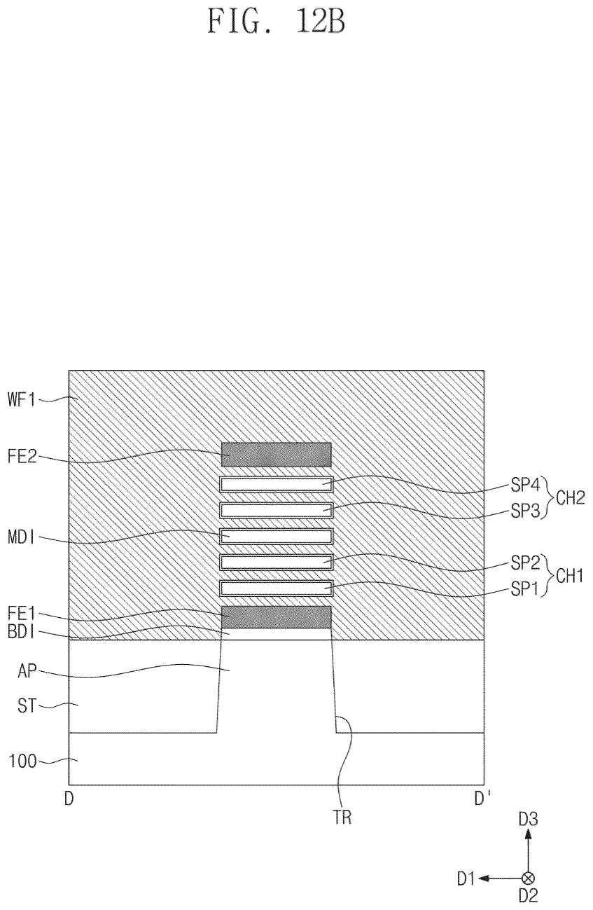

Referring to FIGS. 12A and 12B, the gate insulating layer GI may be conformally formed on the exposed first to fourth semiconductor patterns SP1 to SP4. A first work-function metal layer WF1 may be formed on the gate insulating layer GI. The first work-function metal layer WF1 may be formed in the first to sixth inner regions IRG1 to IRG6. In addition, the first work-function metal layer WF1 may be formed in the outer region ORG to cover the second ferroelectric pattern FE2.

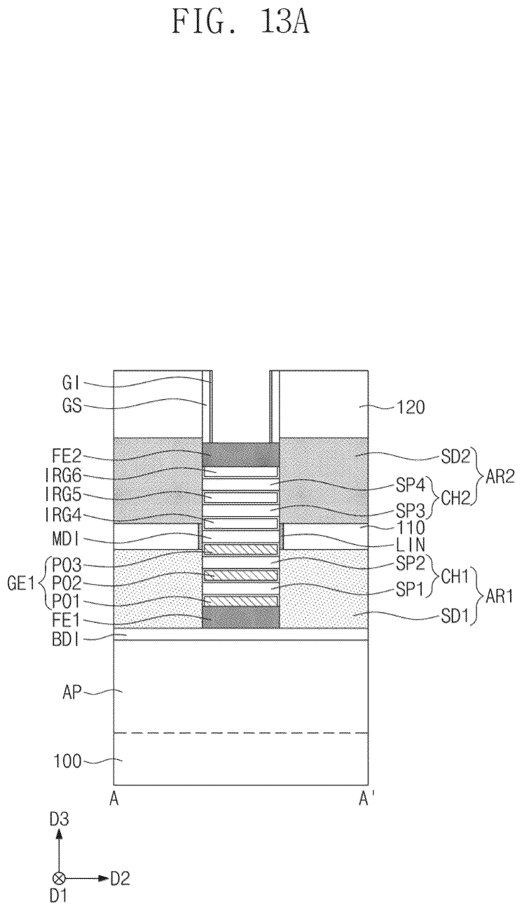

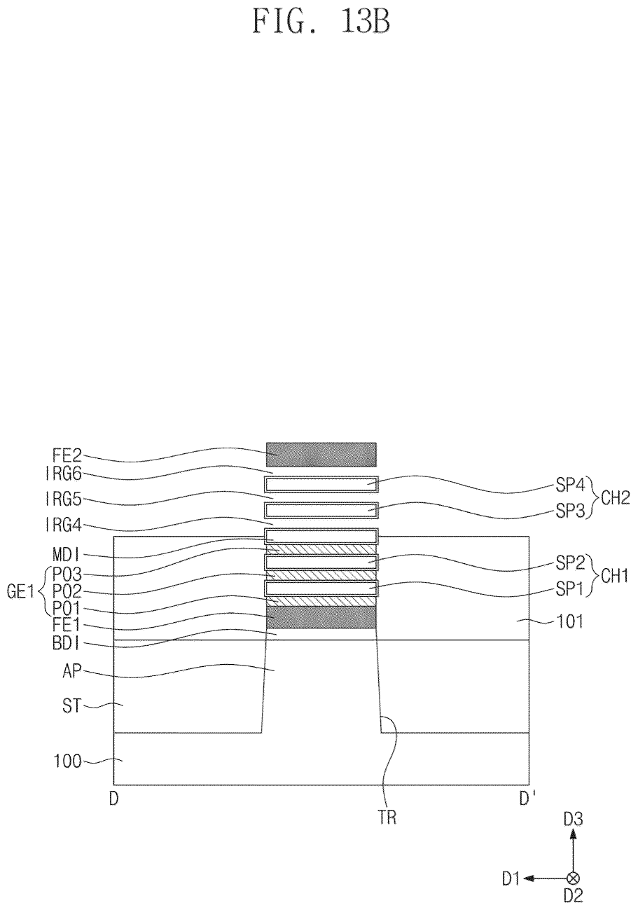

Referring to FIGS. 13A and 13B, the first gate electrode GE1 may be formed by removing a portion of the first work-function metal layer WF1. The first work-function metal layer WF1 may be removed from all regions except the first to third inner regions IRG1 to IRG3. Portions of the first work-function metal layer WF1, which are left in the first to third inner regions IRG1 to IRG3, may constitute first to third portions PO1 to PO3. The first gate electrode GE1 may include the first to third portions PO1 to PO3.

As a result of the partial removal of the first work-function metal layer WF1, the fourth to sixth inner regions IRG4 to IRG6 may be evacuated again. In addition, as a result of the partial removal of the first work-function metal layer WF1, the side surfaces of the first gate electrode GE1 and the first channel pattern CH1 may be exposed to the outside. An outer sacrificial layer 101 may be formed on the exposed side surfaces of the first gate electrode GE1. A top surface of the outer sacrificial layer 101 may be higher than a top surface of the third portion PO3 of the first gate electrode GE1 and may be lower than a top surface of the intermediate insulating layer MDI. The outer sacrificial layer 101 may be formed to prevent the side surfaces of the first gate electrode GE1 and the first channel pattern CH1 from being exposed to the outside. By contrast, the outer sacrificial layer 101 may be formed to expose the fourth to sixth inner regions IRG4 to IRG6.

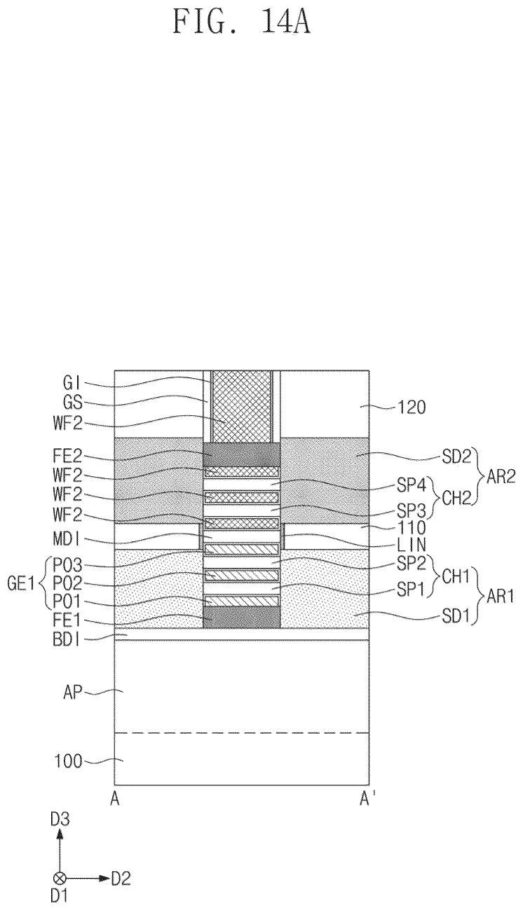

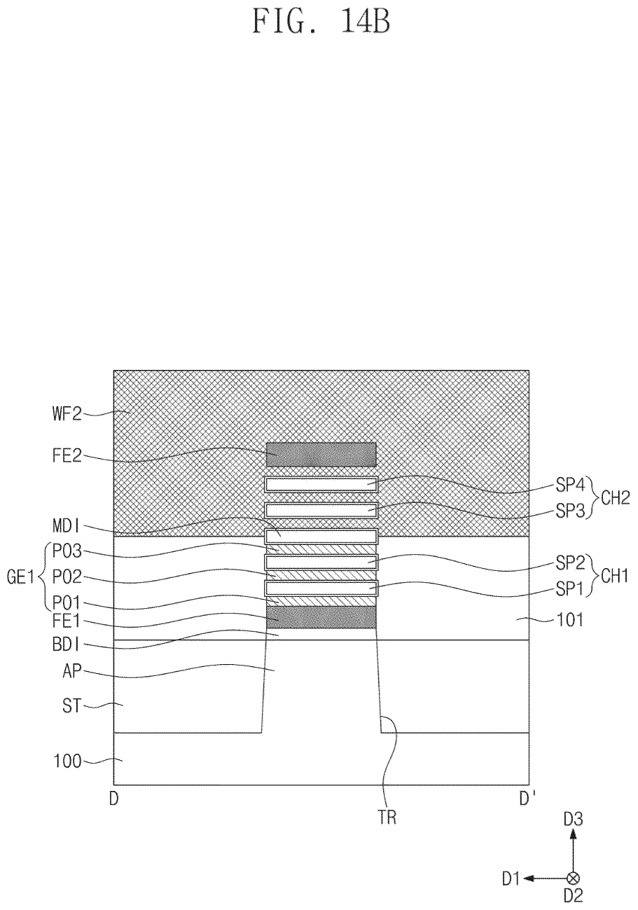

Referring to FIGS. 14A and 14B, a second work-function metal layer WF2 may be formed on the outer sacrificial layer 101 to fill the fourth to sixth inner regions IRG4 to IRG6. In addition, the second work-function metal layer WF2 may cover the second ferroelectric pattern FE2.

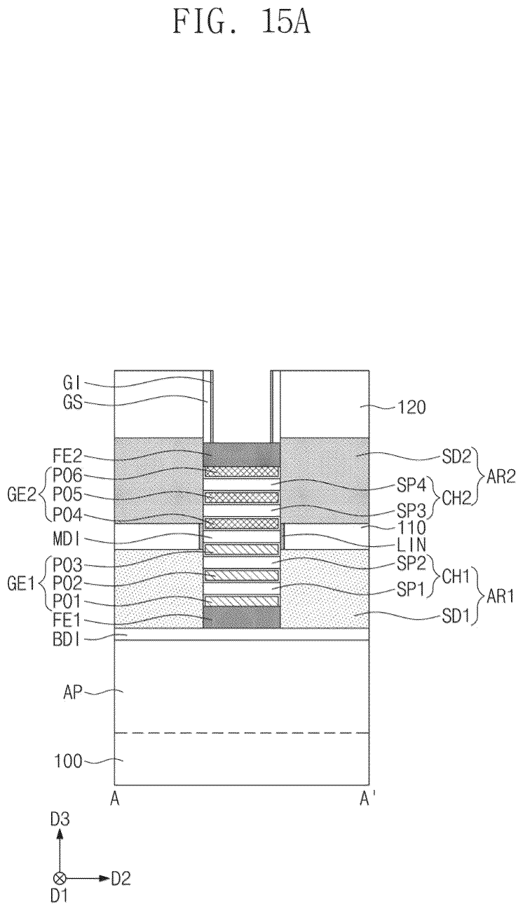

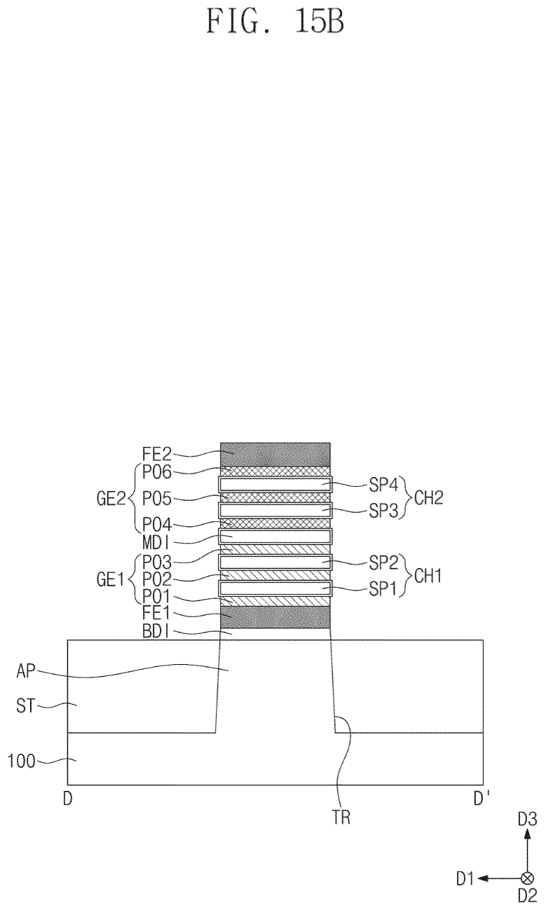

Referring to FIGS. 15A and 15B, a portion of the second work-function metal layer WF2 may be removed to form the second gate electrode GE2. Next, the second work-function metal layer WF2 may be removed from all regions except the fourth to sixth inner regions IRG4 to IRG6. Portions of the second work-function metal layer WF2, which are left in the fourth to sixth inner regions IRG4 to IRG6, may constitute fourth to sixth portions PO4 to PO6. The second gate electrode GE2 may include the fourth to sixth portions PO4 to PO6.

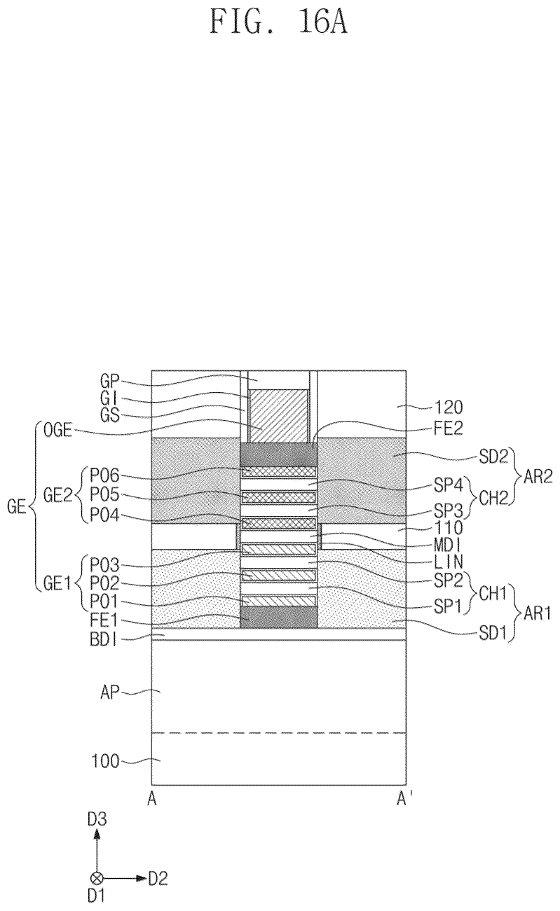

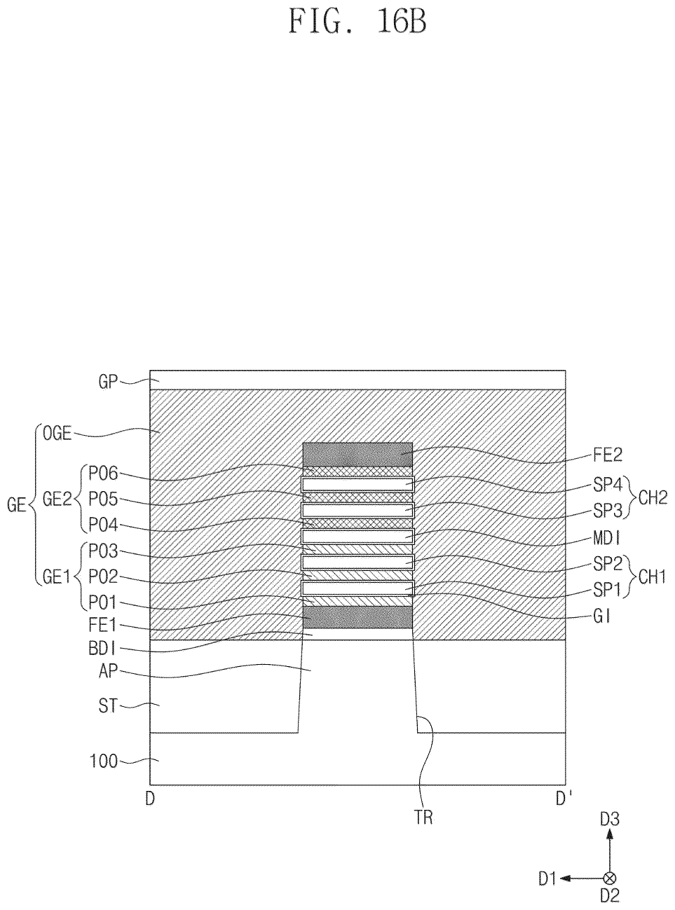

Referring to FIGS. 16A and 16B, the outer gate electrode OGE may be formed. The outer gate electrode OGE may cover exposed side surfaces of the first and second gate electrodes GE1 and GE2 and may extend from the top surface of the device isolation layer ST in the vertical direction D3. The outer gate electrode OGE may cover the second ferroelectric pattern FE2. The first and second gate electrodes GE1 and GE2 and the outer gate electrode OGE may constitute the gate electrode GE.

The outer gate electrode OGE may be recessed to have a reduced height. The gate capping pattern GP may be formed on the recessed outer gate electrode OGE. A planarization process may be performed on the gate capping pattern GP such that a top surface of the gate capping pattern GP is coplanar with the top surface of the second interlayer insulating layer 120.

Referring back to FIGS. 2A to 2D, the first to fourth active contacts AC1 to AC4 may be formed at both (i.e., opposite) sides of the gate electrode GE. For example, the formation of the first to fourth active contacts AC1 to AC4 may include forming first to fourth contact holes, forming active layers to fill the first to fourth contact holes, and planarizing the active layers to expose the top surface of the second interlayer insulating layer 120. The upper separation structures USS may be respectively formed between the first and second active contacts AC1 and AC2 and the second source/drain patterns SD2. For example, the formation of the upper separation structure USS may include selectively performing a wet etching process on the second source/drain patterns SD2 to form a recessed region, after the forming of the first and second contact holes, depositing an insulating material in the first and second contact holes, and performing an anisotropic etching process on the insulating material in the first and second contact holes. The lower separation structures LSS may be respectively formed between the third and fourth active contacts AC3 and AC4 and the first source/drain patterns SD1. The formation of the lower separation structure LSS may be formed through the same process as that for the upper separation structure USS.

Referring back to FIGS. 1 and 2A to 2D, the third interlayer insulating layer 130 may be formed on the second interlayer insulating layer 120. The gate contact GC, which is coupled to the gate electrode GE, may be formed to penetrate the third interlayer insulating layer 130 and the gate capping pattern GP. The connection lines CNL, which are connected to the first to fourth active contacts AC1 to AC4, respectively, may be formed in the third interlayer insulating layer 130.

The fourth interlayer insulating layer 140 may be formed on the third interlayer insulating layer 130. The first metal layer M1 may be formed in the fourth interlayer insulating layer 140. The formation of the first metal layer M1 may include forming first to third interconnection lines MI1 to MI3 in an upper portion of the fourth interlayer insulating layer 140.

The via VI may be formed below each of the first to third interconnection lines MI1 to MI3. As an example, the vias VI may be formed before the formation of the first to third interconnection lines MI1 to MI3. As another example, the vias VI and the first to third interconnection lines MI1 to MI3 may be formed by a dual damascene process.

A plurality of additional metal layers (e.g., M2, M3, M4, and so forth) may be further formed on the first metal layer M1. The first metal layer M1 and the additional metal layers (e.g., M2, M3, M4, and so forth) may constitute a BEOL layer of the semiconductor device.

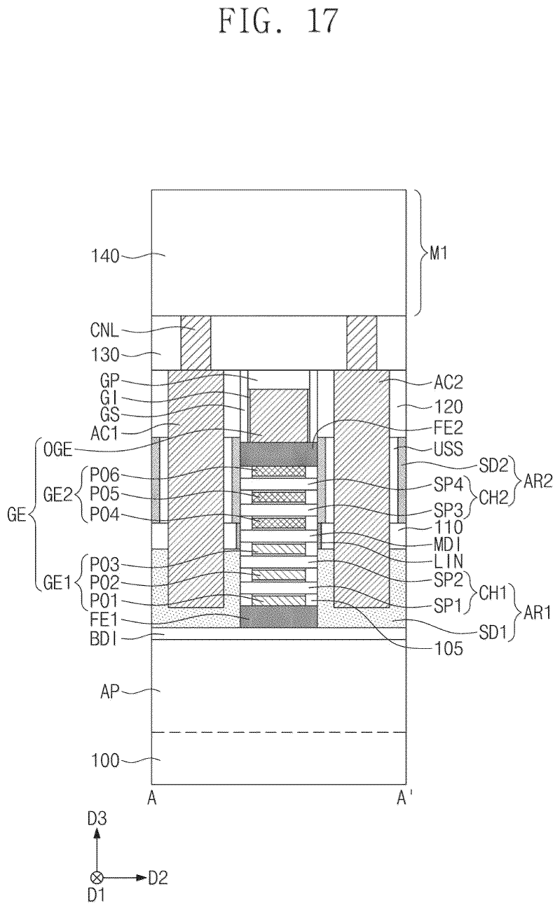

FIGS. 17 to 26 are sectional views, which are respectively taken along the line A-A′ of FIG. 1 to illustrate three-dimensional semiconductor devices according to embodiments. For concise description, an element previously described with reference to FIGS. 1 and 2A to 2D may be identified by the same reference number without repeating an overlapping description thereof.

Referring to FIG. 17, spacer patterns 105 may be disposed on side surfaces of the first and second gate electrodes GE1 and GE2. Some of the spacer patterns 105 may be interposed between the first gate electrode GE1 and the first source/drain patterns SD1, and others of the spacer patterns 105 may be interposed between the second gate electrode GE2 and the second source/drain patterns SD2. The spacer patterns 105 may prevent the source/drain patterns from being contaminated in the fabrication process. In this case, the electrical and reliability characteristics of the three-dimensional semiconductor device may be improved.

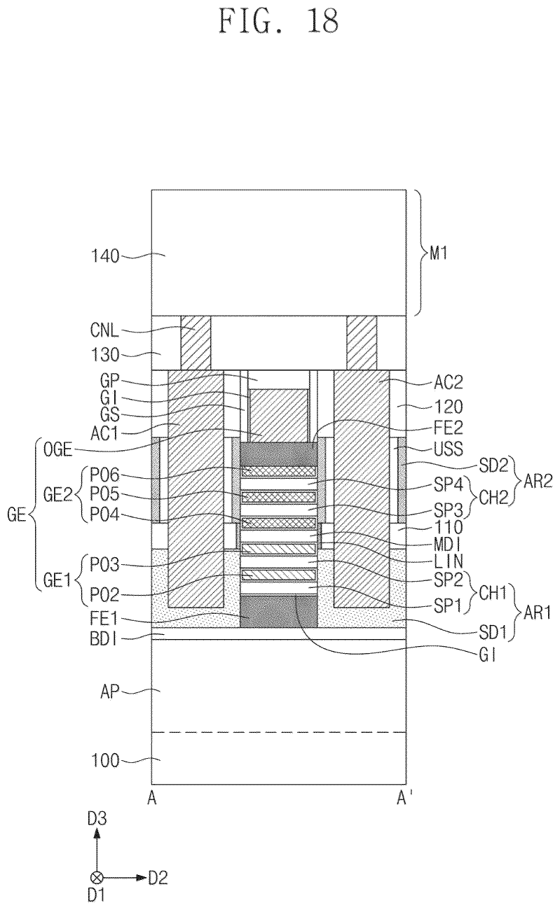

Referring to FIG. 18, the first portion PO1 of the first gate electrode GE1 may be omitted. The gate insulating layer GI may be disposed between the first semiconductor pattern SP1 of the first channel pattern CH1 and the first ferroelectric pattern FE1. In this regard, the first gate electrode GE1 may include fewer portions than the second gate electrode GE2. In an embodiment, the lowermost electrode of the first gate electrode GE1 in contact with the first ferroelectric pattern FE1 may be omitted. In this regard, the lower transistor may have the MFIS structure of the outer gate electrode OGE, the first ferroelectric pattern FE1, the gate insulating layer GI, and the first semiconductor pattern SP1. Thus, it may be possible to realize an NCFET device having the MFIS structure and to prevent an interface property between silicon and an ferroelectric material from being deteriorated.

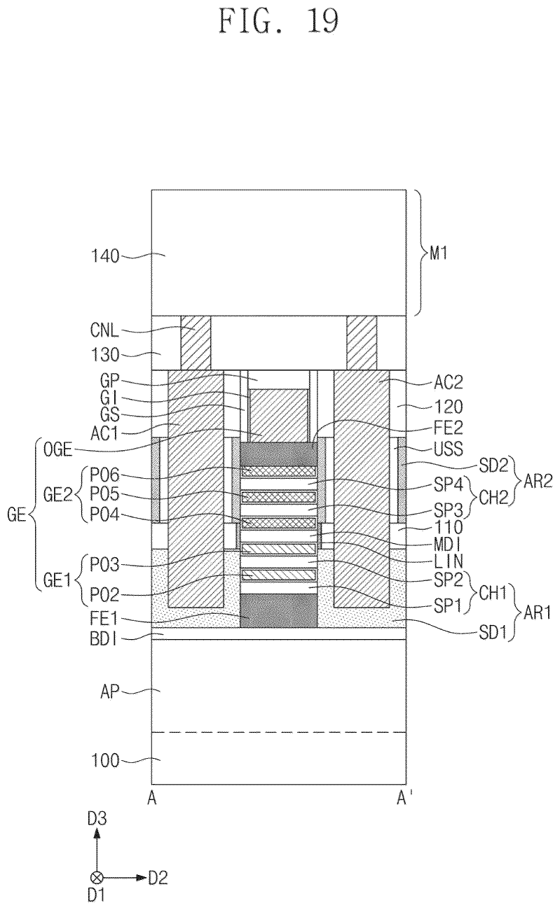

Referring to FIG. 19, the first portion PO1 of the first gate electrode GE1 may be omitted. In addition, the gate insulating layer GI between the first ferroelectric pattern FE1 and the first semiconductor pattern SP1 may be omitted. That is, the lower transistor may have the MFS structure of the outer gate electrode OGE, the first ferroelectric pattern FE1, and the first semiconductor pattern SP1. Thus, it may be possible to realize an NCFET device, to improve the sub-threshold swing characteristics of the transistor, and to lower an operation voltage of the NCFET device.

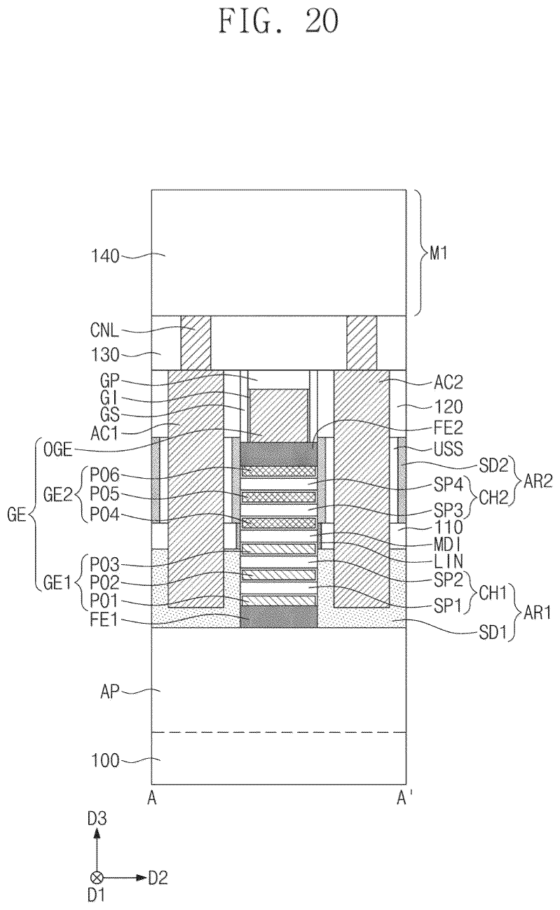

Referring to FIG. 20, the lower insulating layer BDI may be omitted. Thus, it may be possible to reduce the number of process operations and the fabrication cost, compared with embodiments consistent with FIGS. 2A to 2D.

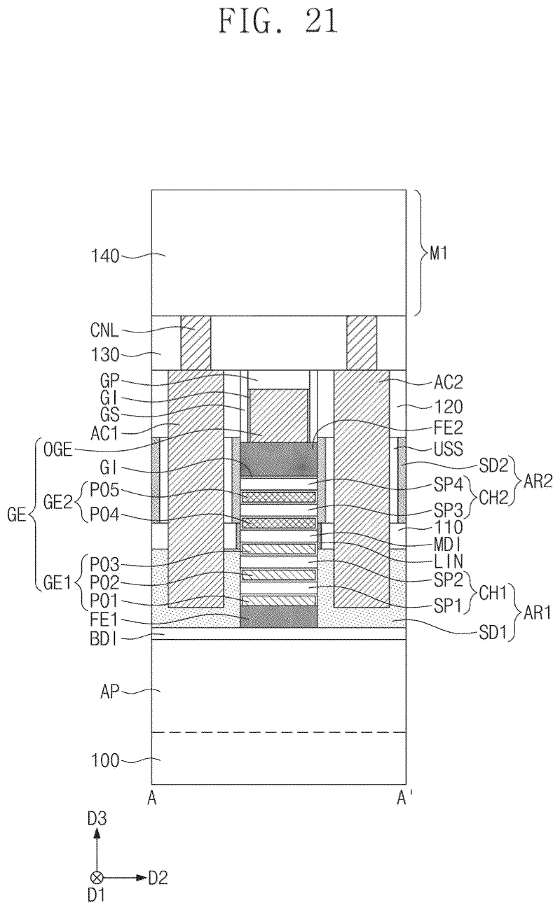

Referring to FIG. 21, the sixth portion PO6 of the second gate electrode GE2 may be omitted. The gate insulating layer GI may be disposed between the fourth semiconductor pattern SP4 of the second channel pattern CH2 and the second ferroelectric pattern FE2. The first gate electrode GE1 may include more portions than the second gate electrode GE2. In an embodiment, the uppermost electrode of the second gate electrode GE2 in contact with the second ferroelectric pattern FE2 may be omitted. In this regard, the upper transistor may have the MFIS structure of the outer gate electrode OGE, the second ferroelectric pattern FE2, the gate insulating layer GI, and the fourth semiconductor pattern SP4.

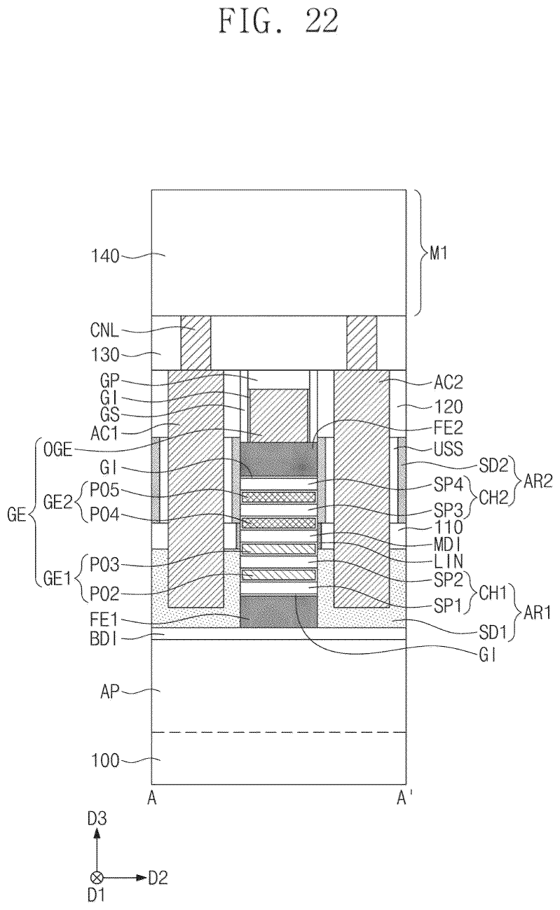

Referring to FIG. 22, the first portion PO1 of the first gate electrode GE1 may be omitted. The gate insulating layer GI may be disposed between the first semiconductor pattern SP1 of the first channel pattern CH1 and the first ferroelectric pattern FE1. In addition, the sixth portion PO6 of the second gate electrode GE2 may be omitted. The gate insulating layer GI may be disposed between the fourth semiconductor pattern SP4 of the second channel pattern CH2 and the second ferroelectric pattern FE2. In this regard, the lower and upper transistors may have the MFIS structure.

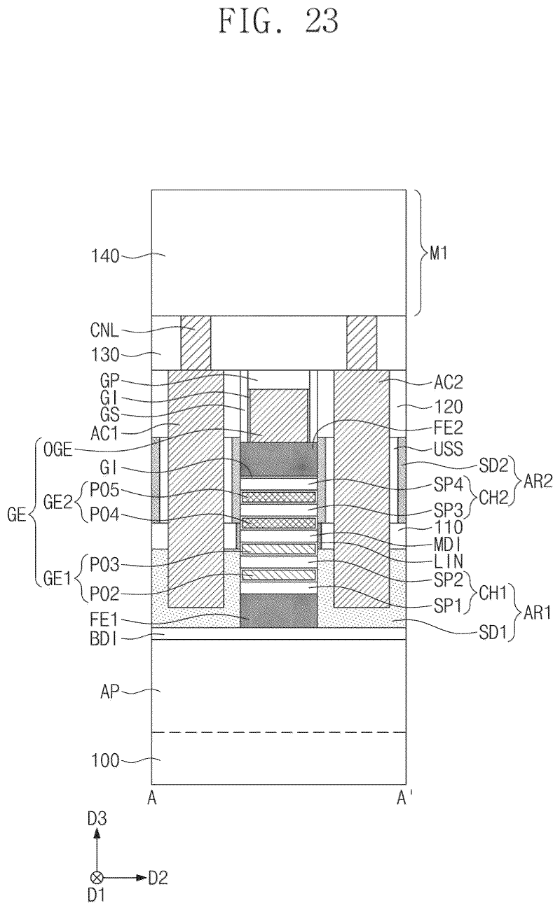

Referring to FIG. 23, the first portion PO1 of the first gate electrode GE1 may be omitted. In addition, the gate insulating layer GI between the first ferroelectric pattern FE1 and the first semiconductor pattern SP1 may be omitted. The sixth portion PO6 of the second gate electrode GE2 may be omitted. The gate insulating layer GI may be disposed between the fourth semiconductor pattern SP4 of the second channel pattern CH2 and the second ferroelectric pattern FE2. In this regard, the lower transistor may have the MFS structure, and the upper transistor may have the MFIS structure.

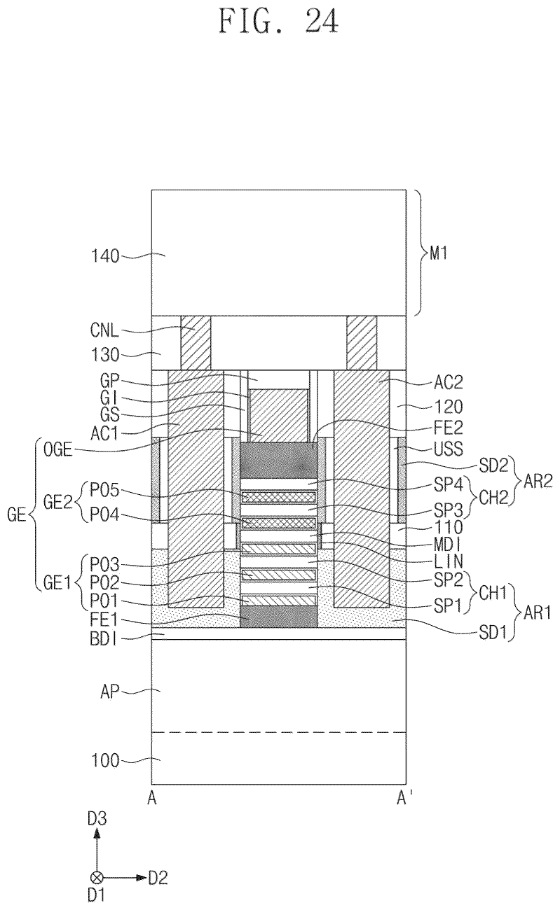

Referring to FIG. 24, the sixth portion PO6 of the second gate electrode GE2 may be omitted. In addition, the gate insulating layer GI between the second ferroelectric pattern FE2 and the fourth semiconductor pattern SP4 may be omitted. In this regard, the upper transistor may have the MFS structure of the outer gate electrode OGE, the second ferroelectric pattern FE2, and the fourth semiconductor pattern SP4.

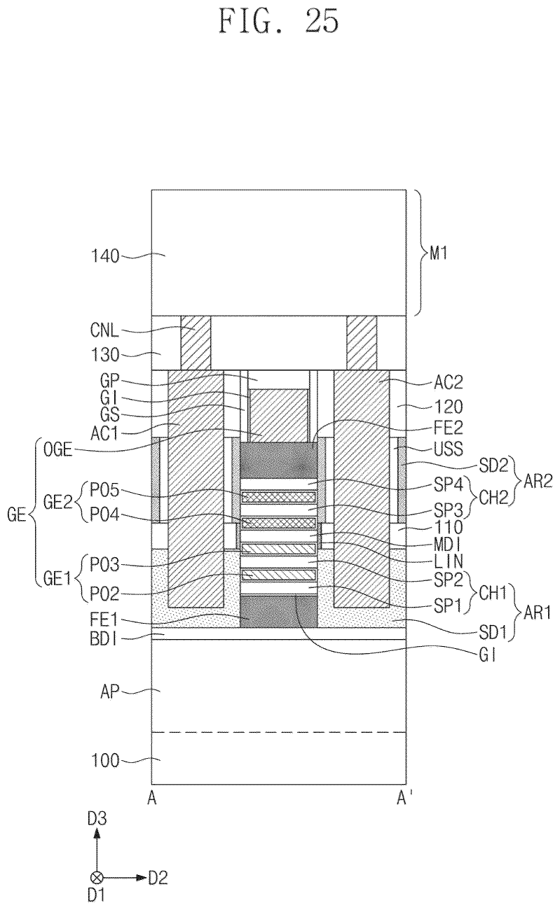

Referring to FIG. 25, the sixth portion PO6 of the second gate electrode GE2 may be omitted. In addition, the gate insulating layer GI between the second ferroelectric pattern FE2 and the fourth semiconductor pattern SP4 may be omitted. The first portion PO1 of the first gate electrode GE1 may be omitted. The gate insulating layer GI may be disposed between the first semiconductor pattern SP1 of the first channel pattern CH1 and the first ferroelectric pattern FE1. In this regard, the upper transistor may have the MFS structure, and the lower transistor may have the MFIS structure.

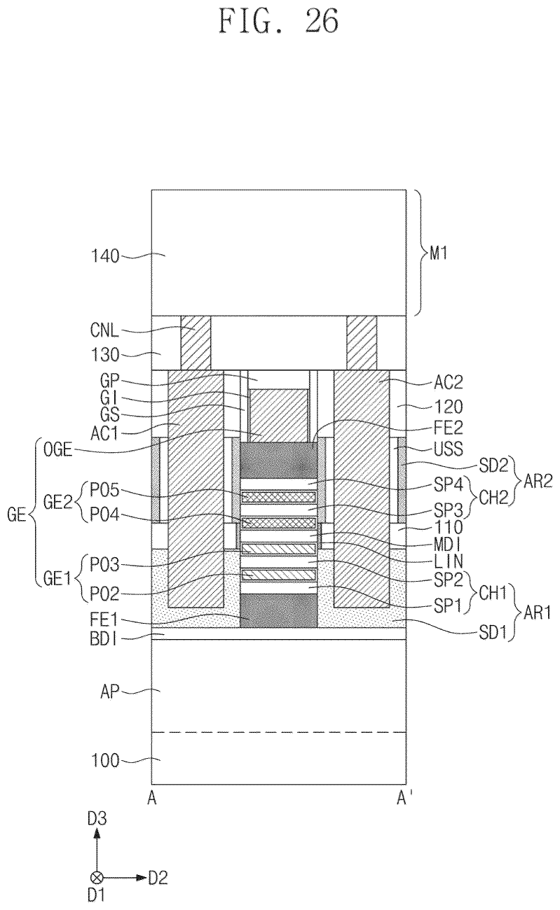

Referring to FIG. 26, the sixth portion PO6 of the second gate electrode GE2 may be omitted. In addition, the gate insulating layer GI between the second ferroelectric pattern FE2 and the fourth semiconductor pattern SP4 may be omitted. The first portion PO1 of the first gate electrode GE1 may be omitted. In addition, the gate insulating layer GI between the first ferroelectric pattern FE1 and the first semiconductor pattern SP1 may be omitted. In this regard, the upper and lower transistors may have the MFS structure.

In a three-dimensional semiconductor device according to an embodiment, a lower transistor may include a ferroelectric material. Thus, the lower transistor may be used as a negative capacitance field effect transistor (NCFET). In this case, the sub-threshold swing characteristics of the transistor may be improved, and an operation voltage of the transistor may be reduced.

While aspects of embodiments have been particularly shown and described, it will be understood that various changes in form and details may be made therein without departing from the spirit and scope of the following claims.

What is claimed is:

1. A three-dimensional semiconductor device, comprising:
a first active region on a substrate, the first active region comprising a first channel pattern and a first source/drain pattern that is connected to the first channel pattern;
a second active region stacked on the first active region, the second active region comprising a second channel pattern and a second source/drain pattern that is connected to the second channel pattern;
a gate electrode disposed on the first and second channel patterns; and
a first ferroelectric pattern interposed between the substrate and the first channel pattern,
wherein the first channel pattern comprises a first semiconductor pattern and a second semiconductor pattern, which are spaced apart from each other in a vertical direction perpendicular to a top surface of the substrate,
wherein the first ferroelectric pattern is interposed between the substrate and the first semiconductor pattern and is disposed at a side of the first source/drain pattern, and
wherein the gate electrode comprises a first gate electrode interposed between the first and second semiconductor patterns.

2. The three-dimensional semiconductor device of claim 1, further comprising a gate insulating layer interposed between each of the first and second semiconductor patterns and the first gate electrode.

3. The three-dimensional semiconductor device of claim 1, further comprising a gate insulating layer interposed between each of the first and second semiconductor patterns and the first gate electrode,
wherein the first gate electrode comprises:
a first portion interposed between the first ferroelectric pattern and the first semiconductor pattern;
a second portion interposed between the first semiconductor pattern and the second semiconductor pattern; and
a third portion disposed on the second semiconductor pattern.

4. The three-dimensional semiconductor device of claim 3, further comprising a second ferroelectric pattern, which is disposed on the second channel pattern and at a side of the second source/drain pattern,
wherein the second channel pattern comprises a third semiconductor pattern and a fourth semiconductor pattern, which are spaced apart from each other in the vertical direction,
wherein the gate electrode further comprises a second gate electrode, which is interposed between the third and fourth semiconductor patterns, and an outer gate electrode, which is provided on the fourth semiconductor pattern, and
wherein the second ferroelectric pattern is interposed between the fourth semiconductor pattern and the outer gate electrode.

5. The three-dimensional semiconductor device of claim 4, wherein the gate insulating layer extends between the third semiconductor pattern and the second gate electrode, between the fourth semiconductor pattern and the second gate electrode, and between the fourth semiconductor pattern and the second ferroelectric pattern.

6. The three-dimensional semiconductor device of claim 4, wherein the second gate electrode comprises:
a fourth portion disposed below the third semiconductor pattern;
a fifth portion interposed between the third semiconductor pattern and the fourth semiconductor pattern; and
a sixth portion interposed between the fourth semiconductor pattern and the second ferroelectric pattern, and
wherein the gate insulating layer extends between the third semiconductor pattern and the second gate electrode, and between the fourth semiconductor pattern and the second gate electrode.

7. The three-dimensional semiconductor device of claim 1, further comprising a lower insulating layer interposed between the substrate and the first ferroelectric pattern.

8. The three-dimensional semiconductor device of claim 1, further comprising an intermediate insulating layer interposed between the first channel pattern and the second channel pattern.

9. The three-dimensional semiconductor device of claim 1, wherein the first source/drain pattern has a first conductivity type, and
wherein the second source/drain pattern has a second conductivity type different from the first conductivity type.

10. A three-dimensional semiconductor device, comprising:
a first active region on a substrate, the first active region comprising a first channel pattern and first source/drain patterns, which are disposed at opposite sides of the first channel pattern, wherein the first channel pattern comprises a plurality of lower semiconductor patterns, which are spaced apart from each other in a vertical direction perpendicular to a top surface of the substrate;
a second active region stacked on the first active region, the second active region comprising a second channel pattern and second source/drain patterns, which are disposed at opposite sides of the second channel pattern;
a gate electrode disposed on the first and second channel patterns, the gate electrode comprising a first gate electrode between the first source/drain patterns, a second gate electrode between the second source/drain patterns, and an outer gate electrode on the second channel pattern; and
a first ferroelectric pattern interposed between a lowermost one of the plurality of lower semiconductor patterns and the substrate, and between the first source/drain patterns.

11. The three-dimensional semiconductor device of claim 10, wherein the first gate electrode is interposed between the plurality of lower semiconductor patterns, and
wherein the three-dimensional semiconductor device further comprises a gate insulating layer, which is interposed between each of the plurality of lower semiconductor patterns and the first gate electrode, and between the lowermost one of the plurality of lower semiconductor patterns and the first ferroelectric pattern.

12. The three-dimensional semiconductor device of claim 10, wherein the first gate electrode comprises:
lower inner electrodes interposed between the plurality of lower semiconductor patterns; and
a lowermost electrode interposed between the first ferroelectric pattern and the lowermost one of the plurality of lower semiconductor patterns, and
wherein the three-dimensional semiconductor device further comprises a gate insulating layer interposed between each of the plurality of lower semiconductor patterns and the first gate electrode.

13. The three-dimensional semiconductor device of claim 12, further comprising a second ferroelectric pattern, which is disposed on the second channel pattern and is interposed between the second source/drain patterns,
wherein the second channel pattern comprises a plurality of upper semiconductor patterns, which are spaced apart from each other in the vertical direction,
wherein the second gate electrode is interposed between the plurality of upper semiconductor patterns, and
wherein the second ferroelectric pattern is interposed between an uppermost one of the plurality of upper semiconductor patterns and the outer gate electrode.

14. The three-dimensional semiconductor device of claim 13, wherein the gate insulating layer extends between each of the plurality of upper semiconductor patterns and the second gate electrode, and between the uppermost one of the plurality of upper semiconductor patterns and the second ferroelectric pattern.

15. The three-dimensional semiconductor device of claim 13, wherein the second gate electrode comprises:
upper inner electrodes interposed between the plurality of upper semiconductor patterns; and
an uppermost electrode interposed between the uppermost one of the plurality of upper semiconductor patterns and the second ferroelectric pattern, and
wherein the gate insulating layer extends between each of the plurality of upper semiconductor patterns and the second gate electrode.

16. The three-dimensional semiconductor device of claim 10, further comprising:
a lower insulating layer interposed between the substrate and the first ferroelectric pattern; and
an intermediate insulating layer interposed between the first channel pattern and the second channel pattern.

17. A three-dimensional semiconductor device, comprising:
a substrate comprising an active pattern;
a lower insulating layer disposed on the active pattern;
a first active region on the lower insulating layer, the first active region comprising a first channel pattern and first source/drain patterns disposed at opposite sides of the first channel pattern, the first channel pattern comprising a first semiconductor pattern and a second semiconductor pattern that is spaced apart from the first semiconductor pattern in a vertical direction perpendicular to a top surface of the substrate;
a second active region stacked on the first active region, the second active region comprising a second channel pattern and second source/drain patterns disposed at opposite sides of the second channel pattern, the second channel pattern comprising a third semiconductor pattern and a fourth semiconductor pattern that is spaced apart from the third semiconductor pattern in the vertical direction;
a gate electrode disposed on the first and second channel patterns, and extending in the vertical direction;
an intermediate insulating layer interposed between the first channel pattern and the second channel pattern;
a first ferroelectric pattern interposed between the substrate and the first semiconductor pattern, and between the first source/drain patterns; and
a second ferroelectric pattern provided on the fourth semiconductor pattern and interposed between the second source/drain patterns.

18. The three-dimensional semiconductor device of claim 17, wherein the gate electrode comprises a first gate electrode between the first and second semiconductor patterns, a second gate electrode between the third and fourth semiconductor patterns, and an outer gate electrode, which is disposed on the fourth semiconductor pattern and is connected to the first and second gate electrodes,
wherein the first gate electrode comprises:
a first portion interposed between the first ferroelectric pattern and the first semiconductor pattern;
a second portion interposed between the first semiconductor pattern and the second semiconductor pattern; and
a third portion disposed on the second semiconductor pattern,
wherein the second gate electrode comprises:
a fourth portion disposed below the third semiconductor pattern;
a fifth portion interposed between the third semiconductor pattern and the fourth semiconductor pattern; and
a sixth portion interposed between the fourth semiconductor pattern and the second ferroelectric pattern, and
wherein the three-dimensional semiconductor device further comprises a gate insulating layer, which is interposed between the first semiconductor pattern and the first gate electrode, between the second semiconductor pattern and the first gate electrode, between the third semiconductor pattern and the second gate electrode, and between the fourth semiconductor pattern and the second gate electrode.

19. The three-dimensional semiconductor device of claim 18, further comprising:
a first active contact and a second active contact electrically connected to the first source/drain patterns; and
a third active contact and a fourth active contact electrically connected to the second source/drain patterns.

20. The three-dimensional semiconductor device of claim 19, further comprising a metal layer on each of the first to fourth active contacts,
wherein the metal layer comprises interconnection lines which are electrically connected to the first to fourth active contacts.
